(19) United States
(12) Patent Application Publication
(10) Pub. No.: US 2024/0339378 A1
(43) Pub. Date: Oct. 10, 2024

(54) SEMICONDUCTOR DEVICE

(71) Applicant: Samsung Electronics Co., Ltd., Suwon-si (KR)

(72) Inventor: Jong Ryeol YOO, Suwon-si (KR)

(73) Assignee: Samsung Electronics Co., Ltd., Suwon-si (KR)

(21) Appl. No.: 18/473,665

(22) Filed: Sep. 25, 2023

(30) Foreign Application Priority Data
Apr. 6, 2023 (KR) 10-2023-0045349

(51) Int. Cl. H01L 23/48; H01L 21/768

(52) U.S. Cl. CPC H01L 23/481; H01L 21/76805; H01L 21/76898; H01L 21/76804; H01L 23/5226; H01L 23/5286; H01L 27/092

(57) ABSTRACT

A semiconductor device includes a substrate including a substrate having a first side and a second side, a source/drain pattern on a fin-shaped pattern and connected to the fin-shaped pattern, a source/drain contact on the source/drain pattern and connected to the source/drain pattern, and a buried conductive pattern includes a first portion and a second portion, the second portion of between the first portion of the buried conductive pattern and a contact connecting via, at the first portion of the buried conductive pattern a width of the buried conductive pattern in a third direction decreases as the buried conductive pattern goes away from a back wiring line, and at the second portion of the buried conductive pattern, the width of the buried conductive pattern in the third direction increases, as the buried conductive pattern goes away from the back wiring line.

### CROSS-REFERENCE TO RELATED APPLICATION

This application claims priority from Korean Patent Application No. 10-2023-0045349 filed on Apr. 6, 2023 in the Korean Intellectual Property Office, and all the benefits accruing therefrom under 35 U.S.C. 119, the contents of which in its entirety are herein incorporated by reference.

### BACKGROUND

Various example embodiments relate to a semiconductor device.

As one of scaling technologies for increasing density of the semiconductor device, a multi-gate transistor has been proposed, in which a multi-channel active pattern (and/or a silicon body) having a fin or nanowire shape is formed on a substrate, and a gate is formed on a surface of the multi-channel active pattern.

Since such a multi gate transistor utilizes a three-dimensional channel, scaling is more easily performed. Additionally or alternatively, even if a gate length of the multi gate transistor is not increased, the current control capability may be improved. Additionally or alternatively, a SCE (short channel effect) in which potential of a channel region is influenced by a drain voltage may be effectively suppressed.

On the other hand, as a pitch size of the semiconductor device becomes smaller, there is a need or desire for a research for reducing the capacitance between contacts in the semiconductor device, and/or ensuring or helping to ensure electrical stability.

### SUMMARY

Aspects of various example embodiments may provide semiconductor device capable of improving element performance and/or reliability.

According to some example embodiments, there is provided a semiconductor device comprising a substrate including a first side and a second side that are opposite to each other in a first direction, a fin-shaped pattern protruding from the first side of the substrate in the first direction, and extending in a second direction, a source/drain pattern on the fin-shaped pattern and connected to the fin-shaped pattern, a source/drain contact on the source/drain pattern and connected to the source/drain pattern, a back wiring line on the second side of the substrate, a contact connecting via connected to the source/drain contact, and extending in the first direction, and a buried conductive pattern inside the substrate, and connecting the contact connecting via and the back wiring line. The buried conductive pattern includes a first portion and a second portion. The second portion of the buried conductive pattern is between the first portion of the buried conductive pattern and the contact connecting via. At the first portion of the buried conductive pattern, a width in a third direction of the buried conductive pattern decreases, as the buried conductive pattern goes away from the back wiring line. At the second portion of the buried conductive pattern, the width in the third direction of the buried conductive pattern increases, as the buried conductive pattern goes away from the back wiring line.

Additionally or alternatively according to some example embodiments, there is provided a semiconductor device comprising a substrate including a first side and a second side that are opposite to each other in a first direction, a fin-shaped pattern protruding from the first side of the substrate in the first direction and extending in a second direction, a source/drain pattern on the fin-shaped pattern and connected to the fin-shaped pattern, a source/drain contact on the source/drain pattern and connected to the source/drain pattern, a back wiring line on the second side of the substrate, a contact connecting via connected to the source/drain contact and extending in the first direction, a buried conductive pattern inside the substrate, and connecting the contact connecting via and the back wiring line, and a connecting via silicide film between the buried conductive pattern and the contact connecting via. The buried conductive pattern includes a first portion and a second portion. The second portion of the buried conductive pattern is between the first portion of the buried conductive pattern and the contact connecting via. At the first portion of the buried conductive pattern, a width in a third direction of the buried conductive pattern is constant. At the second portion of the buried conductive pattern, the width in the third direction of the buried conductive pattern increases, as the buried conductive pattern goes away from the back wiring line.

Additionally or alternatively according to various example embodiments, there is provided a semiconductor device comprising a substrate including a first side and a second side that are opposite to each other in a first direction, a fin-shaped pattern protruding from the first side of the substrate in the first direction and extending in a second direction, a source/drain pattern on the fin-shaped pattern and connected to the fin-shaped pattern, a source/drain contact on the source/drain pattern and connected to the source/drain pattern, a back wiring line on the second side of the substrate, a contact connecting via connected to the source/drain contact and extending in the first direction; and a buried conductive pattern inside the substrate and connecting the contact connecting via and the back wiring line. The buried conductive pattern includes a first portion and a second portion, the second portion of the buried conductive pattern is between the first portion of the buried conductive pattern and the contact connecting via, the first portion of the buried conductive pattern has a line shape extending in the first direction, and the second portion of the buried conductive pattern protrudes from the first portion of the buried conductive pattern in the first direction.

However, aspects of inventive concepts are not restricted to the one set forth herein. The above and other aspects of inventive concepts will become more apparent to one of ordinary skill in the art to which the example embodiments pertain by referencing the detailed description given below.

### BRIEF DESCRIPTION OF THE DRAWINGS

The above and other aspects and/or features of inventive concepts will become more apparent by describing in detail example embodiments thereof with reference to the attached drawings, in which:

FIG. 1 is a layout diagram for explaining the semiconductor device according to some example embodiments.

FIGS. 2 to 7 are cross-sectional views taken along A-A, B-B, C-C, D-D, E-E and F-F of FIG. 1.

FIG. 8 is an enlarged view of a portion P of FIG. 4.

FIGS. 9 to 17 are diagrams for explaining a semiconductor device according to some example embodiments, respectively.

FIGS. 18 to 21 are diagrams for explaining a semiconductor device according to some example embodiments, respectively.

FIGS. 22 to 24 are diagrams for explaining a semiconductor device according to some example embodiments, respectively.

FIGS. 25 and 26 are diagrams for explaining a semiconductor device according to some example embodiments.

FIG. 27 is a layout diagram for explaining a semiconductor device according to some example embodiments.

FIGS. 28 to 32 are cross-sectional views taken along A-A, C-C, D-D, F-F and G-G of FIG. 27.

FIG. 33 is a diagram for explaining a semiconductor device according to some example embodiments.

FIGS. 34 to 41 are intermediate step diagrams for describing a method for fabricating the semiconductor device according to some example embodiments.

FIGS. 42 to 46 are intermediate step diagrams for describing a method for fabricating the semiconductor device according to some example embodiments.

### DETAILED DESCRIPTION OF VARIOUS EXAMPLE EMBODIMENTS

Although terms such as first and second are used to describe various elements or components used herein, these elements or components are not limited by these terms. These terms are only used to distinguish a single element or component from other elements or components. Therefore, a first element or component referred to below may be a second element or component within the technical idea of the present disclosure.

Although drawings according to a semiconductor device according to some example embodiments show a fin-shaped transistor (FinFET) including a channel region of a fin-shaped pattern shape, a transistor including a nanowire or a nanosheet, and a MBCFET™ (Multi-Bridge Channel Field Effect Transistor) as an example, example embodiments are not limited thereto.

The semiconductor device according to some example embodiments may include a tunneling transistor (tunneling FET), a three-dimensional (3D) transistor or a vertical transistor (Vertical FET). The semiconductor device according to some example embodiments may include a planar transistor. In addition, the technical idea of the present disclosure may be applied to a transistor based on two-dimensional material (2D material based FETs) and a heterostructure thereof. Further, the semiconductor device according to some example embodiments may also include a bipolar junction transistor, a laterally diffused metal oxide semiconductor (LDMOS), or the like.

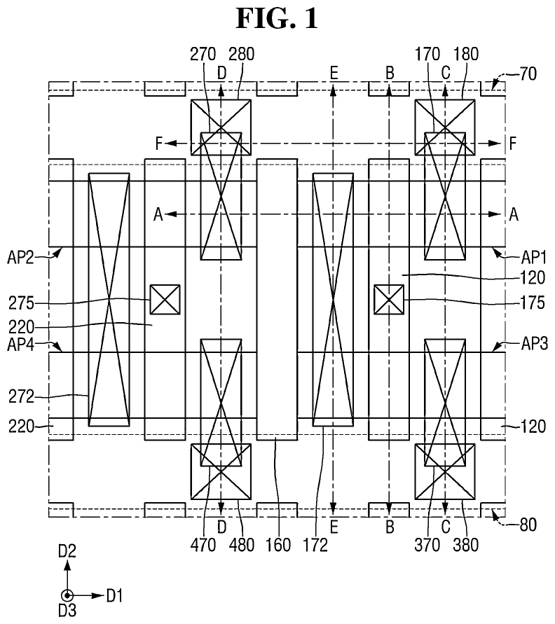

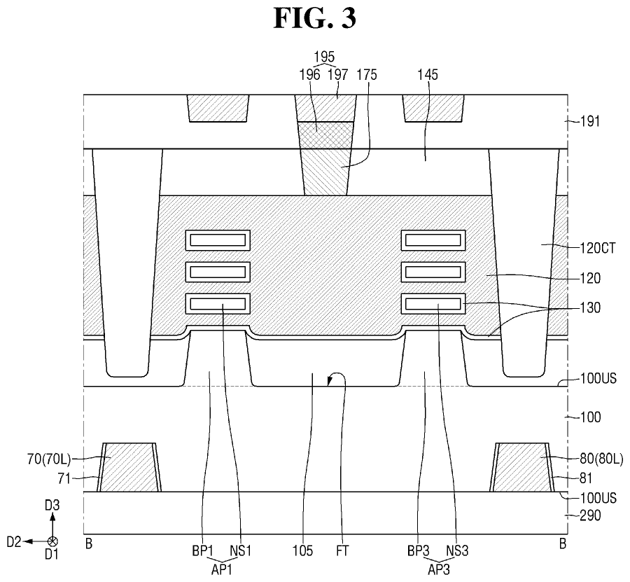

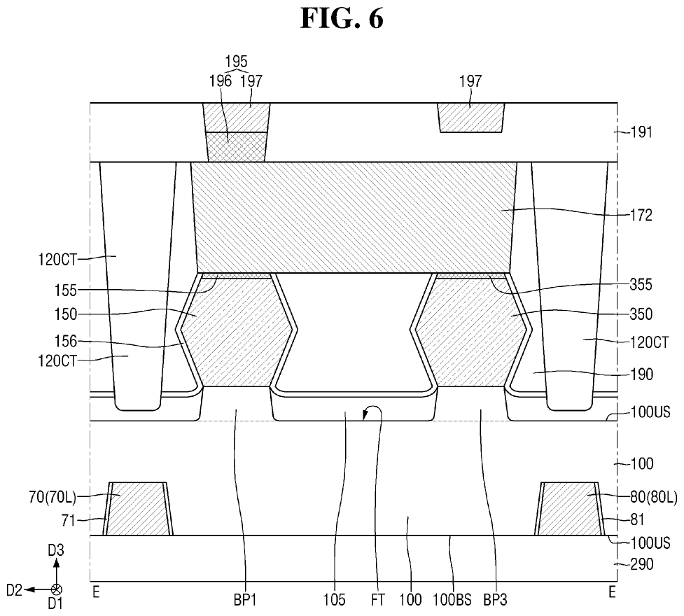

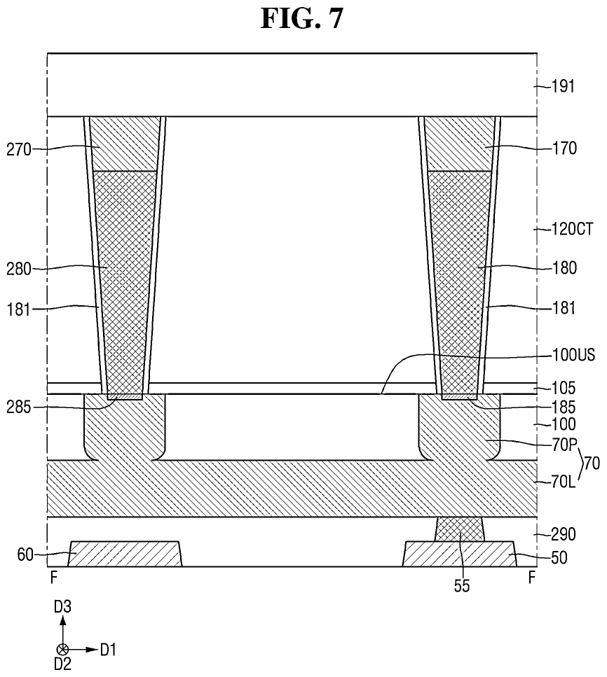

The semiconductor device according to some example embodiments will be described with reference to FIGS. 1 to 8.

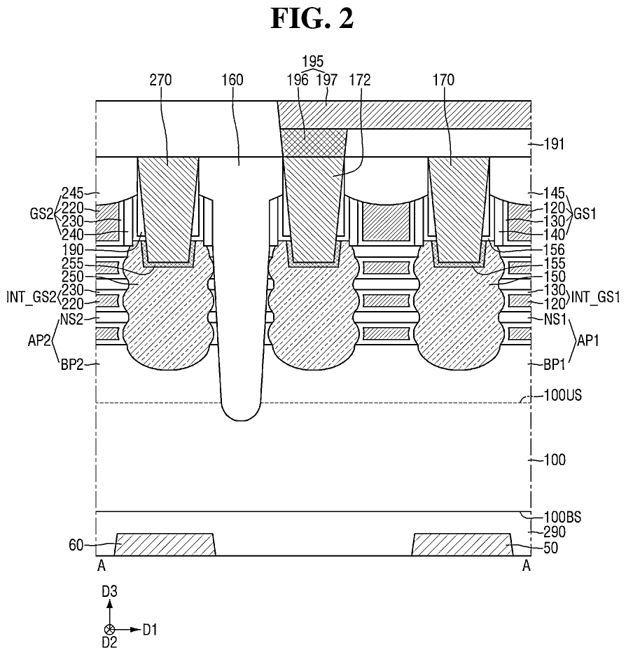

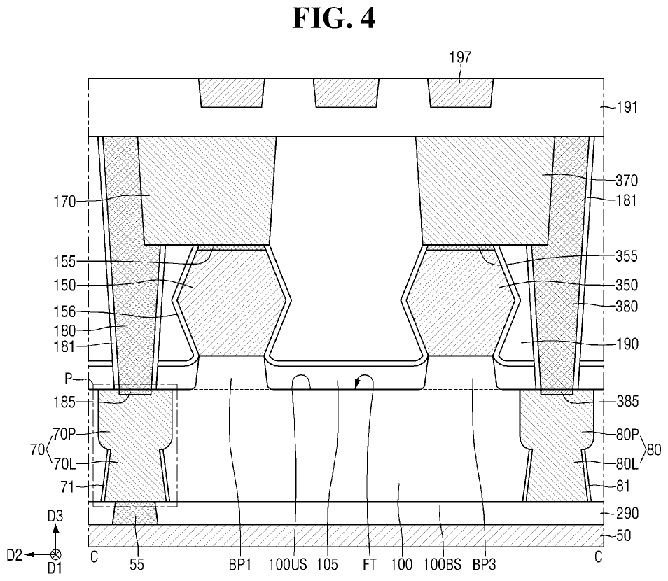

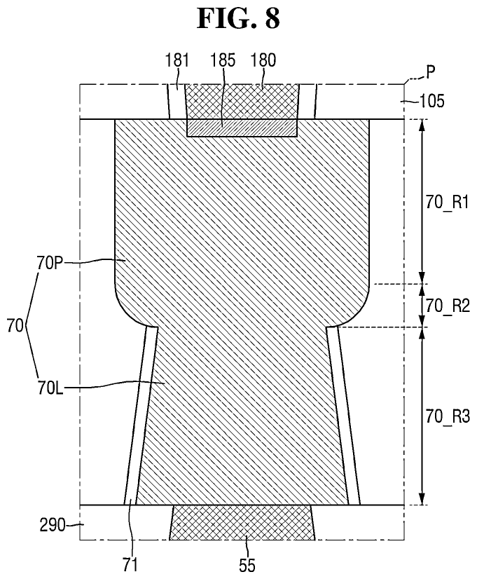

FIG. 1 is a layout diagram for explaining the semiconductor device according to some example embodiments. FIGS. 2 to 7 are cross-sectional views taken along A-A, B-B, C-C. D-D, E-E and F-F, respectively, of FIG. 1. FIG. 8 is an enlarged view of a portion P of FIG. 4.

For convenience of explanation, a front wiring line 197 and a front wiring via 196 are not shown in FIG. 1.

Referring to FIGS. 1 to 8, the semiconductor device according to various example embodiments may include a first active pattern AP1, a second active pattern AP2, a third active pattern AP3, a fourth active pattern AP4, and a first back wiring line 50, a second back wiring line 60, a first buried conductive pattern 70, a second buried conductive pattern 80, a first gate electrode 120, a second gate electrode 220, a first source/drain pattern 150, a second source/drain pattern 250, a third source/drain pattern 350, a fourth source/drain pattern 450, a first element isolation structure 160, a first source/drain contact 170, a second source/drain contact 270, a third source/drain contact 370, a fourth source/drain contact 470, a first contact connecting via 180, a second contact connecting via 280, a third contact connecting via 380, a four contact connecting via 480, and a front wiring structure 195.

The substrate 100 may have or include a first side 100US and a second side 100BS that are opposite to each other in a third (vertical) direction D3, that may be orthogonal either or both of the first side 100US or the second side 100BS. Because the first gate electrode 120 and the source/drain patterns 150, 250, 350 and 450 may be disposed on the first side 100US of the substrate, the first side 100US of the substrate may be or may correspond to an upper side of the substrate 100. The second side 100BS of the substrate opposite to the first side 100US of the substrate may be a lower side of the substrate 100.

The substrate 100 may be made of or include a semiconductor material a semiconductor material. The substrate 100 may be or include, for example, a silicon substrate such as a single-crystal silicon substrate. In some example embodiments, the substrate 100 may include, for example, but is not limited to, one or more of silicon germanium, indium antimonide, lead telluride, indium arsenide, indium phosphide, gallium arsenide or gallium antimonide. In the semiconductor device according to some example embodiments, the substrate 100 may be or include a semiconductor substrate. In some example embodiments, the substrate 100 may be doped, e.g., may be lightly doped; however, example embodiments are not limited thereto.

Each of the active patterns AP1, AP2, AP3 and AP4 may be disposed on the substrate 100. For example, each of the active patterns AP1, AP2, AP3 and AP4 may be disposed on the first side 100US of the substrate. Each of the active patterns AP1, AP2, AP3 and AP4 may extend long in a first (horizontal) direction D1. The first direction D1 may be orthogonal to the third direction D3, and may be parallel to either or both of the front side 100US and the back side 100BS of the substrate.

The first active pattern AP1 may be spaced apart from the second active pattern AP2 in the first direction D1. The first active pattern AP1 and the second active pattern AP2 may be aligned in a line along the first direction D1.

The third active pattern AP3 may be spaced apart from the fourth active pattern AP4 in the first direction D1. The third active pattern AP3 and the fourth active pattern AP4 may be aligned in a line along the first direction D1.

The first active pattern AP1 may be spaced apart from the third active pattern AP3 in a second (horizontal) direction D2. The second direction D2 may be orthogonal to the first direction D1. The second active pattern AP2 may be spaced apart from the fourth active pattern AP4 in the second direction D2.

The first active pattern AP1 and the second active pattern AP2 may be disposed in a region in which transistors of the same conductivity type (e.g., all NMOS transistors, or all PMOS transistors) are formed. The third active pattern AP3 and the fourth active pattern AP4 may be disposed in a region in which transistors of the same conductivity type are formed.

For example, the first active pattern AP1 may be disposed in a region in which a P-type transistor is formed; there may not be an N-type transistor in the region containing the first active pattern AP1. The third active pattern AP3 may be disposed in a region in which an N-type transistor is formed; there may not be a P-type transistor in the region containing third active pattern AP3.

Each of the active patterns AP1, AP2, AP3 and AP4 may be or may include or be included in a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. The third active pattern AP3 may include a third lower pattern BP3 and a plurality of third sheet patterns NS3. The fourth active pattern AP4 may include a fourth lower pattern BP4. Although not shown, the fourth active pattern AP4 may include a plurality of fourth sheet patterns, like the third active pattern AP3. In the semiconductor device according to various example embodiments, each of the active patterns AP1, AP2, AP3 and AP4 may be an active pattern including nanosheet or nanowire. In various example embodiments, a thickness (e.g., a thickness in the third direction D3) of each of the plurality of first sheet patterns NS1, the second sheet patterns NS2, and the third sheet patterns NS3 may be the same; alternatively, at least one of the plurality of sheet patterns NS1-NS3 may have a thickness different than others of the plurality of sheet patterns NS1-ND3.

Each of the lower patterns BP1, BP2, BP3 and BP4 may protrude from the substrate 100. For example, each of the lower patterns BP1, BP2, BP3 and BP4 may protrude from the first side 100US of the substrate. Each of the lower patterns BP1, BP2, BP3 and BP4 may be or have a fin-shaped pattern.

Each of the lower patterns BP1, BP2, BP3, and BP4 may extend along in the first direction D1. The first lower pattern BP1 may be spaced apart from the second lower pattern BP2 in the first direction D1. The third lower pattern BP3 may be spaced apart from the fourth lower pattern BP4 in the first direction D1. The first lower pattern BP1 may be spaced apart from the third lower pattern BP3 in the second direction D2. The second lower pattern BP2 may be spaced apart from the fourth lower pattern BP4 in the second direction D2.

Each of the lower patterns BP1, BP2, BP3 and BP4 may be separated by a fin trench FT extending in the first direction D1. For example, the first side 100US of the substrate may be a lower surface of the fin trench FT. Each of the lower patterns BP1, BP2, BP3 and BP4 includes side walls extending in the first direction D1. The side walls of each of the lower patterns BP1, BP2, BP3 and BP4 may be defined by the fin trench FT.

The plurality of first sheet patterns NS1 may be disposed on the first lower pattern BP1. The plurality of first sheet patterns NS1 may be spaced apart from the first lower pattern BP1 in the third direction D3. The plurality of second sheet patterns NS2 may be disposed on the second lower pattern BP2. The plurality of second sheet patterns NS2 may be spaced apart from the second lower patterns BP2 in the third direction D3. The plurality of third sheet patterns NS3 may be disposed on the third lower pattern BP3. The plurality of third sheet patterns NS3 may be spaced apart from the third lower patterns BP3 in the third direction D3.

Although not shown, a plurality of fourth sheet patterns may be disposed on the fourth lower pattern BP4. The plurality of fourth sheet patterns may be spaced apart from the fourth lower pattern BP4 in the third direction D3. The sheet patterns NS1, NS2 and NS3 may be disposed on the first side 100US of the substrate.

Here, the first direction D1 may intersect the second direction D2 and the third direction D3. Also, the second direction D2 may intersect the third direction D3. The third direction D3 may be a thickness direction of the substrate 100.

The sheet patterns NS1, NS2 and NS3 may each include an upper surface and a lower surface that are opposite to each other in the third direction D3. The lower faces of the sheet patterns NS1, NS2, and NS3 may surface the substrate 100. Although three sheet patterns NS1. NS2, and NS3 are shown as being disposed in the third direction D3, this is only for convenience of explanation, and example embodiments are not limited thereto.

The sheet patterns NS1, NS2 and NS3 may each include the uppermost sheet pattern that is farthest from the substrate 100. For example, the upper faces of the active patterns AP1, AP2 and AP3 may be an upper surface of the uppermost sheet pattern among the sheet patterns NS1, NS2 and NS3. The upper surface of the fourth active pattern AP4 may be an upper surface of the uppermost sheet pattern among the fourth sheet patterns.

Each of the lower patterns BP1, BP2, BP3 and BP4 may be formed by etching a part of the substrate 100, and may include an epitaxial layer grown from the substrate 100. There may or may not be an interface between the epitaxial layer and the substrate 100. Each of the lower patterns BP1, BP2, BP3 and BP4 may include silicon and/or germanium which is an elemental semiconductor material. Alternatively or additionally, each of the lower patterns BP1, BP2, BP3, and BP4 may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

Each of the sheet pattern NS1, NS2 and NS3 may include one or both of silicon or germanium which is the elemental semiconductor material, the group IV-IV compound semiconductor or the group III-V compound semiconductor. The first sheet pattern NS1 will be described an example. A width of the first sheet pattern NS1 in the second direction D2 may increase and/or decrease in proportion to the width of the first lower pattern BP1 in the second direction D2. Although each first sheet pattern NS1 disposed on the first lower pattern BP1 is shown to have the same width in the second direction D2, example embodiments are not limited thereto.

A field insulating film 105 is disposed on the substrate 100. For example, the field insulating film 105 may be disposed on the first side 100US of the substrate. The field insulating film 105 may fill all of or at least a part of the fin trench FT that separates the lower patterns BP1, BP2, BP3 and BP4.

The field insulating film 105 may be disposed on the substrate 100 between the lower patterns BP1, BP2, BP3 and BP4. For example, the field insulating film 105 may cover the entire side walls of the lower patterns BP1, BP2, BP3, and BP4. Unlike the shown example, as another example, the field insulating film 105 may fully or at least partially cover side walls of the lower patterns BP1, BP2, BP3, and BP4. In this case, the lower patterns BP1, BP2. BP3, and BP4 may partially protrude beyond the upper surface of the field insulating film 105 in the third direction D3.

The field insulating film 105 does not cover the upper surface of the first lower pattern BP1. The field insulating film 105 does not cover the upper faces of the second to fourth lower patterns BP2, BP3 and BP4. Each of the sheet patterns NS1, NS2, and NS3 are disposed to be higher than the upper surface of the field insulating film 105 on the basis of the first side 100US of the substrate.

The field insulating film 105 may include, for example, an oxide film, a nitride film, an oxynitride film or a combined film thereof. Although the field insulating film 105 is shown as a single film, this is only for convenience of explanation, and example embodiments are not limited thereto.

The first gate structure GS1 and the second gate structure GS2 may be disposed on the first side 100US of the substrate. The first gate structure GS1 and the second gate structure GS2 may each extend in the second direction D2.

The first gate structures GS1 may be spaced apart in the first direction D1. The first gate structures GS1 may be adjacent to each other in the first direction D1.

The second gate structures GS2 may be spaced apart in the first direction D1. The second gate structures GS2 may be adjacent to each other in the first direction D1.

The first gate structure GS1 may be disposed on the first active pattern AP1 and the third active pattern AP3. The first gate structure GS1 may intersect the first active pattern AP1 and the third active pattern AP3.

The first gate structure GS1 may intersect the first lower pattern BP1 and the third lower pattern BP3. The first gate structure GS1 may wrap the respective first sheet patterns NS1. The first gate structures GS1 may wrap the respective third sheet patterns NS3.

The second gate structure GS2 may be disposed on the second active pattern AP2 and the fourth active pattern AP4. The second gate structure GS2 may intersect the second active pattern AP2 and the fourth active pattern AP4.

The second gate structure GS2 may intersect the second lower pattern BP2 and the fourth lower pattern BP4. The second gate structure GS2 may wrap around each second sheet pattern NS2. The second gate structure GS2 may wrap around each fourth sheet pattern.

Although the first gate structure GS1 is shown as being disposed over the first active pattern AP1 and the third active pattern AP3, example embodiments are not limited thereto. Unlike the shown example, a part of the first gate structure GS1 is separated into two portions by a gate isolation structure disposed on the field insulating film 105, and may be disposed on the first active pattern AP1 and the third active pattern AP3. The description of the first gate structure GS1 may be applied to the second gate structure GS2.

The first gate structure GS1 may include, for example, a first gate electrode 120, a first gate insulating film 130, a first gate spacer 140, and a first gate capping pattern 145. The second gate structure GS2 may include, for example, a second gate electrode 220, a second gate insulating film 230, a second gate spacer 240, and a second gate capping pattern 245.

The first gate structures GS1 may include a plurality of first inner gate structures INT_GS1 which are disposed between the first sheet patterns NS1 adjacent in the third direction D3, and between the first lower patterns BP1 and the first sheet patterns NS1. The first inner gate structure INT_GS1 mat be disposed between the upper surface of the first lower pattern BP1 and the lower surface of the first sheet pattern NS1, and between the upper surface of the first sheet pattern NS1 and the lower surface of the first sheet pattern NS1 facing each other in the third direction D3.

The number of first inner gate structures INT_GS1 may be equal to the number of first sheet patterns NS1. The first inner gate structure INT_GS1 is in contact with the upper surface of the first lower pattern BP1, the upper surface of the first sheet pattern NS1, and the lower surface of the first sheet pattern NS1.

The first inner gate structure INT_GS1 includes the first gate electrode 120 and the first gate insulating film 130 disposed between the adjacent first sheet patterns NS1, and between the first lower pattern BP1 and the first sheet pattern NS1. Although not shown, the first inner gate structure INT_GS1 may be disposed between the third sheet patterns NS3 adjacent in the third direction D3, and between the third lower pattern BP3 and the third sheet pattern NS3.

The second gate structure GS2 may include a plurality of second inner gate structures INT_GS2 disposed between the second sheet patterns NS2 adjacent in the third direction D3, and between the second lower pattern BP2 and the second sheet pattern NS2. Although not shown, the second inner gate structure INT_GS2 may be disposed between the fourth sheet patterns adjacent in the third direction D3, and between the fourth lower pattern BP4 and the fourth sheet pattern. The description of the second inner gate structure INT_GS2 may be substantially the same as the description of the first inner gate structure INT_GS1.

The following description will be provided mainly on the first active pattern AP1 and the first gate structure GS1, and the third active pattern AP3 and the first gate structure GS1. The description of the second gate structure GS2 may be substantially the same as the description of the first gate structure GS1.

The first gate electrode 120 may be disposed on the first lower pattern BP1 and the third lower pattern BP3. The first gate electrode 120 may intersect the first lower pattern BP1 and the third lower pattern BP3. The first gate electrode 120 may wrap around the first sheet pattern NS1 and the third sheet pattern NS3.

Although the cross-sectional view of FIG. 2 shows that the upper surface of the first gate electrode 120 is a concavely curved surface, example embodiments are not limited thereto. The upper surface of the first gate electrode 120 may be a flat or planar surface.

The first gate electrode 120 and the second gate electrode 220 may include at least one of metal, metal alloy, conductive metal nitride, metal silicide, doped semiconductor material such as doped polysilicon, conductive metal oxide and conductive metal oxynitride. The first gate electrode 120 and the second gate electrode 220 may include, for example, but are not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include, but are not limited to, oxidized forms of the aforementioned materials.

The first gate insulating film 130 may extend along the upper surface of the field insulating film 105, the upper surface of the first lower pattern BP1, and the upper surface of the third lower pattern BP3. The first gate insulating film 130 may wrap around the plurality of first sheet patterns NS1. The first gate insulating film 130 may wrap around the plurality of third sheet patterns NS3. The first gate insulating film 130 may be disposed along the periphery of the first sheet pattern NS1 and the periphery of the third sheet pattern NS3. The first gate electrode 120 is disposed on the first gate insulating film 130.

The first gate insulating film 130 is disposed between the first gate electrode 120 and the first sheet pattern NS1, and between the first gate electrode 120 and the third sheet pattern NS3. In the semiconductor device according to various example embodiments, the first gate insulating film 130 included in the first inner gate structure INT_GS1 may be in contact with a first source/drain patterns 150, which will be described later.

The first gate insulating film 130 and the second gate insulating film 230 may include silicon oxide, silicon oxynitride, silicon nitride or a high dielectric constant material having a dielectric constant greater than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the first gate insulating film 130 and the second gate insulating film 230 are shown as a single film, this is only for convenience of explanation, and example embodiments are not limited thereto. The first gate insulating film 130 and the second gate insulating film 230 may include a plurality of films. The first gate insulating film 130 will be described as an example. The first gate insulating film 130 may include an interfacial layer disposed between the first active pattern AP1 and the first gate electrode 120, and between the third active pattern AP3 and the first gate electrode 120, and a high dielectric constant insulating film. For example, the interfacial layer may not be formed along the profile of the upper surface the field insulating film 105.

A semiconductor device according to some example embodiments may include a NC (Negative Capacitance) FET that uses a negative capacitor. For example, the first gate insulating film 130 and the second gate insulating film 230 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, an overall capacitance values of the ferroelectric material film and the paraelectric material film connected in series may increase. By the use of the increased overall capacitance value, a transistor including the ferroelectric material film may have a subthreshold swing (SS) that is under 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is or includes aluminum (Al), the ferroelectric material film may include 3 to 8 at % (atomic %) aluminum. Here, a ratio of the dopant may be a ratio of aluminum to the sum of hafnium and aluminum.

When the dopant is or includes silicon (Si), the ferroelectric material film may include 2 to 10 at % silicon. When the dopant is or includes yttrium (Y), the ferroelectric material film may include 2 to 10 at % yttrium. When the dopant is or includes gadolinium (Gd), the ferroelectric material film may include 1 to 7 at % gadolinium. When the dopant is or includes zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material, and may or may not include any other material. The ferroelectric material film has the ferroelectric properties, but the paraelectric material film may not have the ferroelectric properties, and in some example embodiments may depend upon a phase of the film. For example, when the ferroelectric material film and the paraelectric material film include hafnium oxide, a crystal structure of hafnium oxide included in the ferroelectric material film may differ from a crystal structure of hafnium oxide included in the paraelectric material film.

The ferroelectric material film may have a thickness having the ferroelectric properties. A thickness of the ferroelectric material film may be, for example, but is not limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film 130 and the second gate insulating film 230 may include a single ferroelectric material film. As another example, the first gate insulating film 130 and the second gate insulating film 230 may each include a plurality of ferroelectric material films spaced apart from each other. The first gate insulating film 130 and the second gate insulating film 230 may have a stacked film structure in which the plurality of ferroelectric material films and the plurality of paraelectric material films are alternately stacked.

The first gate spacer 140 may be disposed on side walls of the first gate electrode 120. For example, the first gate spacers 140 may be disposed on long side wall of the first gate electrode 120 extending in the second direction D2. The first gate spacer 140 may not be disposed between the first lower pattern BP1 and the first sheet pattern NS1, and between the first sheet patterns NS1 adjacent in the third direction D3.

The second gate spacer 240 may be disposed on side walls of the second gate electrode 220. The second gate spacer 240 may not be disposed between the second lower pattern BP2 and the second sheet pattern NS2, and between the second sheet patterns NS2 adjacent in the third direction D3.

The first gate spacer 140 and the second gate spacer 240 may include, for example, but are not limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the first gate spacer 140 and the second gate spacer 240 are shown as a single film, this is only for convenience of explanation, and example embodiments are not limited thereto.

A first gate capping pattern 145 may be disposed on the first gate electrode 120. An upper surface of the first gate capping pattern 145 may be an upper surface of the first gate structure GS1. A second gate capping pattern 245 may be disposed on the second gate electrode 120. An upper surface of the second gate capping pattern 245 may be an upper surface of the second gate structure GS2.

The first gate capping pattern 145 may be disposed between the first gate spacers 140, unlike the shown example. The second gate capping pattern 245 may be disposed between the second gate spacers 240.

The first gate capping pattern 145 and the second gate capping pattern 245 may include, for example, at least one of silicon nitride (SiN), silicon oxynitride (SiON), silicon carbonitride (SiCN), silicon oxycarbonitride (SiOCN), and combinations thereof. The first gate capping pattern 145 and the second gate capping pattern 245 may or may not be formed at the same time.

Unlike the shown example, the first gate structure GS1 and the second gate structure GS2 may not include the gate capping patterns 145 and 245.

The first source/drain pattern 150 may be disposed on the first lower pattern BP1. The first source/drain pattern 150 may be disposed on a side surface of the first gate electrode 120. The first source/drain pattern 150 may be in contact with the first active pattern AP1. The first source/drain pattern 150 may be in contact with the first sheet pattern NS1. The first source/drain pattern 150 is connected to the first sheet pattern NS1 and the first lower pattern BP1. For example, the first source/drain pattern 150 may be in contact with the first inner gate structure INT_GS1.

The second source/drain pattern 250 may be disposed on the second lower pattern BP2. The second source/drain pattern 250 may be disposed on a side surface of the second gate electrode 220. The second source/drain pattern 250 may be in contact with the second active pattern AP2. The second source/drain pattern 250 may be in contact with the second sheet pattern NS2. The second source/drain pattern 250 is connected to the second sheet pattern NS2 and the second lower pattern BP2. For example, the second source/drain pattern 250 may be in contact with the second inner gate structure INT_GS2.

The third source/drain pattern 350 may be disposed on the third lower pattern BP3. The third source/drain pattern 350 may be disposed on the side surface of the first gate electrode 120. The fourth source/drain pattern 450 may be disposed on the fourth lower pattern BP4. The fourth source/drain pattern 450 may be disposed on the side surface of the second gate electrode 220. Although not shown, the third source/drain pattern 350 may be in contact with the third sheet pattern NS3. The fourth source/drain pattern 450 may be in contact with the fourth sheet pattern.

As an example, a cross-sectional view taken in the first direction D1 along the third active pattern AP3 and the fourth active pattern AP4 may be similar to that of FIG. 2. The third source/drain pattern 350 may be in contact with the first gate insulating film 130 included in the first inner gate structure INT_GS1. The fourth source/drain pattern 450 may be in contact with the second gate insulating film 230 included in the second inner gate structure INT_GS2.

Although not shown, as another example, an inner spacer may be further disposed between the first inner gate structure INT_GS1 and the third source/drain pattern 350, and between the second inner gate structure INT_GS2 and the fourth source/drain pattern 450. In such a case, the third source/drain pattern 350 is not in contact with the first gate insulating film 130 included in the first inner gate structure INT_GS1. The fourth source/drain pattern 450 is not in contact with the second gate insulating film 230 included in the second inner gate structure INT_GS2.

The source/drain patterns 150, 250, 350 and 450 may be disposed on the first side 100US of the substrate. Since the first lower pattern BP1 is spaced apart from the second lower pattern BP2 in the first direction D1, the first source/drain pattern 150 is spaced apart from the second source/drain pattern 250 in the first direction D1. The third source/drain pattern 350 is spaced apart from the fourth source/drain pattern 450 in the first direction D1. The first source/drain pattern 150 is spaced apart from the third source/drain pattern 350 in the second direction D2. The second source/drain pattern 250 is spaced apart from the fourth source/drain pattern 450 in the second direction D2.

The first source/drain pattern 150 may be included in the source/drain of a transistor that uses the first sheet pattern NS1 as a channel region. The second source/drain pattern 250 may be included in the source/drain of the transistor that uses the second sheet pattern NS2 as a channel region. The third source/drain pattern 350 may be included in the source/drain of the transistor that uses the third sheet pattern NS3 as a channel region. The fourth source/drain pattern 450 may be included in the source/drain of the transistor that uses the fourth sheet pattern as the channel region.

Each of the source/drain patterns 150, 250, 350 and 450 may include an epitaxial pattern, and may or may not include the same epitaxial material. Each of the source/drain patterns 150, 250, 350 and 450 may include a semiconductor material.

The first source/drain pattern 150 and the second source/drain pattern 250 may include p-type dopant. The p-type dopant may include, but is not limited to, at least one of boron (B) and gallium (Ga). The third source/drain pattern 350 and the fourth source/drain pattern 450 may include n-type dopant. The n-type dopant may include, but is not limited to, at least one of phosphorus (P), arsenic (As), antimony (Sb), and bismuth (Bi).

In some example embodiments, the first source/drain pattern 150 and the second source/drain pattern 250 may include n-type dopants, for example, at a dopant concentration much less than that of p-type dopants included therein; however, example embodiments are not limited thereto. In some example embodiments, the third source/drain pattern 350 and the fourth source/drain pattern 450 may include p-type dopants, for example, at a dopant concentration much less than n-type dopants included therein; however, example embodiments are not limited thereto.

The source/drain etching stop film 156 may extend along the outer walls of the gate spacers 140 and the side walls of the source/drain patterns 150, 250, 350 and 450. The source/drain etching stop film 156 may extend along the upper surface of the field insulating film 105.

The source/drain etching stop film 156 may not extend along the side walls of the first gate capping pattern 145 and the side walls of the second gate capping pattern 245. Unlike the shown example, the source/drain etching stop film 156 may extend along side walls of the first gate capping pattern 145 and side walls of the second gate capping pattern 245.

The source/drain etching stop film 156 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

A first element isolation structure 160 may be disposed on the substrate 100. The first element isolation structure 160 may be disposed on the first side 100US of the substrate. The first element isolation structure 160 may extend in the second direction D2.

The first element isolation structure 160 may be disposed between the first active pattern AP1 and the second active pattern AP2. The first element isolation structure 160 may be disposed between the third active pattern AP3 and the fourth active pattern AP4. The first element isolation structure 160 may be disposed between the first source/drain pattern 150 and the second source/drain pattern 250. Although not shown, the first element isolation structure 160 may be disposed between the third source/drain pattern 350 and the fourth source/drain pattern 450.

The first element isolation structure 160 may isolate the first lower pattern BP1 and the second lower pattern BP2. The first element isolation structure 160 may isolate the third lower pattern BP3 and the fourth lower pattern BP4. The first lower pattern BP1 and the second lower pattern BP2 may each protrude from the first element isolation structure 160 in the first direction D1. Although not shown, the third lower pattern BP3 and the fourth lower pattern BP4 may each protrude from the first element isolation structure 160 in the first direction D1.

A height of the upper surface of the first element isolation structure 160 may be equal to a height of the upper surface of the first gate capping pattern 145, on the basis of the second side 100BS of the substrate. Unlike the shown example, the upper surface of the first element isolation structure 160 may be higher than the upper surface of the first gate capping pattern 145, on the basis of the second side 100BS of the substrate.

The first element isolation structure 160 may include an insulating material. The first element isolation structure 160 may include, for example, but is not limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the first element isolation structure 160 is shown to be a single film, example embodiments are not limited thereto.

An insulating residual pattern may be disposed between the first element isolation structure 160 and the first source/drain pattern 150. The insulating residual pattern may be disposed between the first element isolation structure 160 and the second source/drain pattern 250. The insulating residual pattern may include the same material as the gate insulating films 130 and 230.

As an example, the first source/drain pattern 150 and the third source/drain pattern 350 may be disposed between the first gate electrodes 120 adjacent in the first direction D1. As another example, the first source/drain pattern 150 and the third source/drain pattern 350 may be disposed between the first gate electrode 120 and the first element isolation structure 160.

As an example, the second source/drain pattern 250 and the fourth source/drain pattern 450 may be disposed between the second gate electrodes 220 adjacent in the first direction D1. As another example, the second source/drain pattern 250 and the fourth source/drain pattern 450 may be disposed between the second gate electrode 220 and the first element isolation structure 160.

A gate isolation structure 120CT may be disposed on the field insulating film 105. A part of the gate isolation structure 120CT may penetrate into the field insulating film 105.

The gate isolation structures 120CT may be disposed to be spaced apart in the second direction D2. The active patterns AP1, AP2, AP3 and AP4 may be disposed between the first gate isolation structures GCS1 adjacent in the second direction D2.

The first gate electrode 120 and the second gate electrode 220 may be disposed between the gate isolation structures 120CT adjacent in the second direction D2. The gate isolation structure 120CT may isolate the gate electrodes adjacent in the second direction D2. When the first gate electrode 120 and the second gate electrode 220 include short side walls extending in the first direction D1, the short side wall of the first gate electrode 120 and the short side wall of the second gate electrode 220 look the gate isolation structure 120CT.

For example, the gate isolation structures 120CT may be disposed along a boundary of a standard cell. For example, the gate isolation structure 120CT may be or may include or be included in a standard cell isolation structure.

The gate isolation structure 120CT may include, for example, but is not limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the gate isolation structure 120CT is shown to be a single film, example embodiments are not limited thereto.

The upper surface of the gate isolation structure 120CT may be disposed on the same plane as the upper surface of the first gate capping pattern 145, but is not limited thereto.

A first upper interlayer insulating film 190 is disposed on the first side 100US of the substrate. The first upper interlayer insulating film 190 may be disposed on the source/drain patterns 150, 250, 350 and 450. The first upper interlayer insulating film 190 may be disposed on the source/drain etching stop film 156.

The first upper interlayer insulating film 190 may not cover the upper surface of the first gate capping pattern 145 and the upper surface of the second gate capping pattern 245. The first upper interlayer insulating film 190 may include, for example, at least one of silicon oxide, silicon nitride, silicon oxynitride, and a low dielectric constant material such as but not limited to a porous material. The dielectric constant of the low dielectric constant material may have a value smaller than 3.9, which is the dielectric constant of silicon oxide.

The first source/drain contact 170 may be disposed on the first side 100US of the substrate. The first source/drain contact 170 may be disposed on the first source/drain pattern 150. The first source/drain contact 170 is electrically connected to the first source/drain pattern 150.

The first source/drain contact 170 may be connected to the first back wiring line 50, for example, through the first contact connecting via 180. Although not shown, a part of the first source/drain contact 170 may not be connected to the first contact connecting via 180.

The second source/drain contact 270 may be disposed on the first side 100US of the substrate. The second source/drain contact 270 may be disposed on the second source/drain pattern 250. The second source/drain contact 270 is electrically connected to the second source/drain pattern 250.

The second source/drain contact 270 may be connected to the first back wiring line 50 through the second contact connecting via 280. Although not shown, a part of the second source/drain contact 270 may not be connected to the second contact connecting via 280.

A third source/drain contact 370 may be disposed on the first side 100US of the substrate. The third source/drain contact 370 may be disposed on the third source/drain pattern 350. The third source/drain contact 370 is electrically connected to the third source/drain pattern 350.

The third source/drain contact 370 may be connected to the second back wiring line 60 through the third contact connecting via 380. Although not shown, a part of the third source/drain contact 370 may not be connected to the third contact connecting via 380.

A fourth source/drain contact 470 may be disposed on the first side 100US of the substrate. The fourth source/drain contact 470 may be disposed on the fourth source/drain pattern 450. The fourth source/drain contact 470 is electrically connected to the fourth source/drain pattern 450.

The fourth source/drain contact 470 may be connected to the second back wiring line 60 through a fourth contact connecting via 480. Although not shown, a part of the fourth source/drain contact 470 may not be connected to the fourth contact connecting via 480.

A first connecting source/drain contact 172 may be disposed on the first source/drain pattern 150 and the third source/drain pattern 350. The first connecting source/drain contact 172 is electrically connected to the first source/drain pattern 150 and the third source/drain pattern 350.

A second connecting source/drain contact 272 may be disposed on the second source/drain pattern 250 and the fourth source/drain pattern 450. The second connecting source/drain contact 272 is electrically connected to the second source/drain pattern 250 and the fourth source/drain pattern 450. The first connecting source/drain contact 172 and the second connecting source/drain contact 272 may not be electrically connected to the first back wiring line 50 and the second back wiring line 60.

The upper surface of the first source/drain contact 170 may be coplanar with the upper surface of the second source/drain contact 270. For example, a height of the upper surface of the first source/drain contact 170 may be equal to a height of the upper surface of the second source/drain contact 270 on the basis of the upper surface of the field insulating film 105. The height of the upper surface of the first source/drain contact 170 may be equal to the height of the upper surface of the third source/drain contact 370 and the height of the upper surface of the fourth source/drain contact 470, on the basis of the upper surface of the field insulating film 105.

A first contact silicide film 155 may be disposed between the first source/drain contact 170 and the first source/drain pattern 150, and between the first connecting source/drain contact 172 and the first source/drain pattern 150. A second contact silicide film 255 may be disposed between the second source/drain contact 270 and the second source/drain pattern 250, and between the second connecting source/drain contact 272 and the second source/drain pattern 250. A third contact silicide film 355 may be disposed between the third source/drain contact 370 and the third source/drain pattern 350, and between the first connecting source/drain contact 172 and the third source/drain pattern 350. A fourth contact silicide film 455 may be disposed between the fourth source/drain contact 470 and the fourth source/drain pattern 450, and between the second connecting source/drain contact 272 and the fourth source/drain pattern 450. Each of the first through fourth contact silicide films 155, 255, 355, and 455 may include the same material; however, example embodiments are not limited thereto, and at least one of the first through fourth contact silicide films 155, 255, 355, and 455 may include a different material that is not included in others thereof.

The first gate contact 175 is disposed on the first gate electrode 120. The first gate contact 175 may pass through the first gate capping pattern 145. The first gate contact 175 is connected to the first gate electrode 120. The first gate contact 175 connects the front wiring line 197 and the first gate electrode 120. The second gate contact 275 is disposed on the second gate electrode 220. Although not shown, the second gate contact 275 connects the front wiring line 197 and the second gate electrode 220.

Although the source/drain contacts 170, 270, 370 and 470 and the connecting source/drain contacts 172 and 272 are shown to have a single conductive film structure, example embodiments are not limited thereto. The source/drain contacts 170, 270, 370 and 470 and the connecting source/drain contacts 172 and 272 may have multiple conductive film structures, including barrier films and plug films, unlike the shown example.

Although the first gate contact 175 is shown to have a single conductive film structure, example embodiments are not limited thereto. Unlike the shown example, the first gate contact 175 may have multiple conductive film structures, including barrier films and plug films.

The source/drain contacts 170, 270, 370 and 470, the connecting source/drain contacts 172 and 272, and the gate contacts 175 and 275 may collectively or independently include, for example, at least one of metal, conductive metal nitride, conductive metal carbide, conductive metal oxide, a conductive metal carbonitride, and a two-dimensional material. The contact silicide films 155, 255, 355 and 455 may include a metal silicide material.

The two-dimensional material (2D material) may include a 2D allotrope and/or a 2D compound, and may include, but is not limited to, at least one of graphene, boron nitride (BN), molybdenum sulfide, molybdenum selenide, tungsten sulfide, tungsten selenide, and tantalum sulfide. For example, since the above-mentioned 2D materials are only listed by way of example, the 2D materials that may be included in the semiconductor device of the present disclosure are not limited by the above-mentioned materials.

The first buried conductive pattern 70 and the second buried conductive pattern 80 may be disposed inside the substrate 100. For example, the first buried conductive pattern 70 and the second buried conductive pattern 80 may extend from the second side 100BS of the substrate to the first side 100US of the substrate. In terms of a plan view, the active patterns AP1, AP2, AP3 and AP4 may be disposed between the first buried conductive pattern 70 and the second buried conductive pattern 80.

The first buried conductive pattern 70 may extend along in the first direction D1 along the first active pattern AP1 and the second active pattern AP2. The first buried conductive pattern 70 may be connected to the first back wiring line 50 (see FIG. 4).

The first buried conductive pattern 70 may be connected to the first source/drain contact 170 through the first contact connecting via 180. The first buried conductive pattern 70 may be connected to the second source/drain contact 270 through the second contact connecting via 280.

The second buried conductive pattern 80 may extend long in the first direction D1 along the third active pattern AP3 and the fourth active pattern AP4. The second buried conductive pattern 80 may be connected to the second back wiring line 60.

The second buried conductive pattern 80 may be connected to the third source/drain contact 370 through the third contact connecting via 180. The second buried conductive pattern 80 may be connected to the fourth source/drain contact 470 through the fourth contact connecting via 480.

The first buried conductive pattern 70 may include a first buried conductive line 70L and a plurality of first buried conductive protrusions 70P. The first buried conductive line 70L may have a line shape extending in the first direction D1.

Each first buried conductive protrusion 70P may protrude from the first buried conductive line 70L in the third direction D3. The first buried conductive protrusion 70P may protrude toward the first and second contact connecting vias 180 and 280. The first buried conductive protrusion 70P may have a contact shape such as a circular and/or elliptical shape when viewed in plan view. The plurality of first buried conductive protrusions 70P may be arranged along the first direction D1.

The second buried conductive pattern 80 may include a second buried conductive line 80L and a plurality of second buried conductive protrusions 80P. The second buried conductive line 80L may have a line shape extending in the first direction D1; in some example embodiments, the first buried conductive line 70L and the second buried conductive line 80L may extend parallel to each other.

Each second buried conductive protrusion 80P may protrude from the second buried conductive line 80L in the third direction D3. The second buried conductive protrusion 80P may protrude toward the third and fourth contact connecting vias 380 and 480. The second buried conductive protrusion 80P may have a contact shape such as a circular and/or elliptical shape when viewed in plan view. The plurality of second buried conductive protrusions 80P may be arranged along the first direction D1, and may or may not have the same arrangement as the plurality of first conductive protrusions 70P.

The following description will be provided mainly on the first buried conductive pattern 70. The description regarding the second buried conductive pattern 80 may be substantially the same as the description regarding the first buried conductive pattern 70.

In FIG. 8, the first buried conductive pattern 70 may include a first portion 70_R1, a second portion 70_R2, and a third portion 70_R3. The second portion 70_R2 of the first buried conductive pattern may be disposed between the first portion 70_R1 of the first buried conductive pattern and the third portion 70_R3 of the first buried conductive pattern.

The first and second contact connecting vias 180 and 280 may be connected to the first portion 70_R1 of the first buried conductive pattern. The first portion 70_R1 of the first buried conductive pattern may be disposed between the contact connecting vias 180 and 280 and the second portion 70_R2 of the first buried conductive pattern. The first back wiring line 50 may be connected to the third portion 70_R3 of the first buried conductive pattern. The third portion 70_R3 of the first buried conductive pattern may be disposed between the first back wiring line 50 and the second portion 70_R2 of the first buried conductive pattern.

For example, the first portion 70_R1 of the first buried conductive pattern and the second portion 70_R2 of the first buried conductive pattern may be included in the first buried conductive protrusion 70P. The third portion 70_R3 of the first buried conductive pattern may be included in the first buried conductive line 70L. The third portion 70_R3 of the first buried conductive pattern may have a line shape extending in the first direction D1. The first portion 70_R1 of the first buried conductive pattern and the second portion 70_R2 of the first buried conductive pattern may protrude from the third portion 70_R3 of the first buried conductive pattern in the third direction D3.

At the first portion 70_R1 of the first buried conductive pattern, the width of the first buried conductive pattern 70 in the third direction D3 may be constant, as the first portion 70_R1 goes away from the first back wiring line 50. At the second portion 70_R2 of the first buried conductive pattern, the width of the first buried conductive pattern 70 in the third direction D3 may increase, as the second portion 70_R2 goes away from the first back wiring line 50. At the third portion 70_R3 of the first buried conductive pattern, the width of the first buried conductive pattern 70 in the third direction D3 may decrease or taper upwardly, as the third portion 70_R3 goes away from the first back wiring line 50.

A first buried insulating liner 71 may be disposed on the side wall of the first buried conductive pattern 70. The first buried insulating liner 71 may be disposed between the first buried conductive pattern 70 and the substrate 100. For example, the first buried insulating liner 71 may be disposed on the side wall of the first buried conductive line 70L. The first buried insulating liner 71 may not be disposed on the side wall of the first buried conductive protrusion 70P.

A second buried insulating liner 81 may be disposed on the side wall of the second buried conductive pattern 80. The second buried insulating liner 81 may be disposed between the second buried conductive pattern 80 and the substrate 100. For example, the second buried insulating liner 81 may be disposed on the side wall of the second buried conductive line 80L. The second buried insulating liner 81 may not be disposed on the side wall of the second buried conductive protrusion 80P.

Unlike the shown example, the buried insulating liners 71 and 81 may not be formed between the buried conductive patterns 70 and 80 and the substrate 100.

Although the first buried conductive pattern 70 and the second buried conductive pattern 80 are shown to have a single conductive film structure, example embodiments are not limited thereto. For example, unlike the shown example, one or both of the first buried conductive pattern 70 and the second buried conductive pattern 80 may have multiple conductive film structures, including a buried conductive barrier film and a buried conductive plug film.

The first buried conductive pattern 70 and the second buried conductive pattern 80 may independently or jointly include, for example, at least one of metal, conductive metal nitride, conductive metal carbide, conductive metal oxide, conductive metal carbonitride, and two-dimensional material. The first buried insulating liner 71 and the second buried insulating liner 81 include an insulating material.

The first back wiring line 50 and the second back wiring line 60 may be disposed on the second side 100BS of the substrate. For example, the first back wiring line 50 and the second back wiring line 60 may each extend in the second direction D2, but example embodiments are not limited thereto.

The first back wiring line 50 may be connected to the first buried conductive pattern 70. The first back wiring line 50 may be connected to the first source/drain contact 170 and the second source/drain contact 270 through the first buried conductive pattern 70. The first back wiring line 50 may be connected to the first buried conductive line 70L.

The second back wiring line 60 may be connected to the second buried conductive pattern 80. The second back wiring line 60 may be connected to the third source/drain contact 370 and the fourth source/drain contact 470 through the second buried conductive pattern 80. The second back wiring line 60 may be connected to the second buried conductive line 80L.

As an example, the first back wiring line 50 and the second back wiring line 60 may be or may correspond to or include or be included in power lines that supply power, such as but not limited to Vdd and/or Vss power and/or GND, to the semiconductor device. Alternatively or additionally, the first back wiring line 50 and the second back wiring line 60 may be or include or be included in signal lines that supply operating signal of the semiconductor device. In some example embodiments, one of the first back wiring line 50 and the second back wiring line 60 may be a power line, and another thereof may be a signal line.

The first back wiring via 55 may be disposed between the first back wiring line 50 and the first buried conductive pattern 70. The first back wiring via 55 may connect the first back wiring line 50 and the first buried conductive pattern 70.

A second back wiring via 65 may be disposed between the second back wiring line 60 and the second buried conductive pattern 80. The second back wiring via 65 may connect the second back wiring line 60 and the second buried conductive pattern 80.

Although the first back wiring line 50 and the second back wiring line 60 are shown to have a single conductive film structure, example embodiments are not limited thereto. Unlike the shown example, the first back wiring line 50 and the second back wiring line 60 independently or jointly may have multiple conductive film structures. Although the first back wiring via 55 and the second back wiring via 65 are shown to have a single conductive film structure, example embodiments are not limited thereto.

The first back wiring line 50 and the second back wiring line 60 may independently or jointly include, for example, at least one of metal, conductive metal nitride, conductive metal carbide, conductive metal oxide, conductive metal carbonitride, and a two-dimensional material. The first back wiring via 55 and the second back wiring via 65 may include, for example, at least one of metal, conductive metal nitride, conductive metal carbide, conductive metal oxide, conductive metal carbonitride, and a two-dimensional material.

The first back wiring line 50 and the first back wiring via 55 will be described as an example. Although a boundary between the first back wiring line 50 and the first back wiring via 55 is shown as being divided, example embodiments are not limited thereto. The first back wiring line 50 and the first back wiring via 55 may or may not have an integrated structure with no interface division.

Unlike the shown example, the first back wiring via 55 may not be disposed between the first back wiring line 50 and the first buried conductive pattern 70. The second back wiring via 65 may not be disposed between the second back wiring line 60 and the second buried conductive pattern 80. In such a case, a direction in which the first back wiring line 50 and the second back wiring line 60 extend may differ from that shown.

A lower interlayer insulating film 290 may be disposed on the second side 100BS of the substrate. The first back wiring line 50, the first back wiring via 55, the second back wiring line 60, and the second back wiring via 65 may be disposed in the lower interlayer insulating film 290. The lower interlayer insulating film 290 may include, for example, at least one of silicon oxide, silicon nitride, silicon carbonitride, silicon oxynitride, and a low dielectric constant material.

A first contact connecting via 180 may be disposed between the first source/drain contact 170 and the first buried conductive pattern 70. The first contact connecting via 180 may connect the first source/drain contact 170 and the first buried conductive pattern 70. The first contact connecting via 180 may connect the first source/drain contact 170 and or to the first back wiring line 50. The first contact connecting via 180 overlaps or at least partly overlaps the first source/drain contact 170 in the second direction D2.

A second contact connecting via 280 may be disposed between the second source/drain contact 270 and the first buried conductive pattern 70. The second contact connecting via 280 may connect the second source/drain contact 270 and or to the first buried conductive pattern 70. The second contact connecting via 280 may connect the second source/drain contact 270 and the first back wiring line 50. The second contact connecting via 280 overlaps or at least partly overlaps the second source/drain contact 270 in the second direction D2.

The first contact connecting via 180 and the second contact connecting via 280 pass through the source/drain etching stop film 156, and may be connected to the first buried conductive protrusion 70P. The first contact connecting via 180 may be spaced apart from the second contact connecting via 280 in the first direction D1. The first contact connecting via 180 and the second contact connecting via 280 may be disposed in the first direction D1.

A third contact connecting via 380 may be disposed between the third source/drain contact 370 and the second buried conductive pattern 80. The third contact connecting via 380 may connect the third source/drain contact 370 and the second buried conductive pattern 80. The third contact connecting via 380 may connect the third source/drain contact 370 and the second back wiring line 60. The third contact connecting via 380 overlaps the third source/drain contact 370 in the second direction D2.

A fourth contact connecting via 480 may be disposed between the fourth source/drain contact 470 and the second buried conductive pattern 80. The fourth contact connecting via 480 may connect the fourth source/drain contact 470 and the second buried conductive pattern 80. The fourth contact connecting via 480 may connect the fourth source/drain contact 470 and the second back wiring line 60. The fourth contact connecting via 480 overlaps the fourth source/drain contact 470 in the second direction D2.

The third contact connecting via 380 and the fourth contact connecting via 480 pass through the source/drain etching stop film 156, and may be connected to the second buried conductive protrusion 80P. The third contact connecting via 380 may be spaced apart from the fourth contact connecting via 480 in the first direction D1. The third contact connecting via 380 and the fourth contact connecting via 480 may be arranged in the first direction D1.

Although the first source/drain contact 170 connected to the first contact connecting via 180 is shown as being aligned with the third source/drain contact 370 connected to the third contact connecting via 380 in the second direction D2, this is only for convenience of explanation, and example embodiments are not limited thereto.

The first contact connecting via 180 will be described as an example. The description regarding the second to fourth contact connecting vias 280, 380 and 480 may be substantially the same as the description regarding the first contact connecting via 180.

In the cross-sectional view such as FIG. 4, a part of the first contact connecting via 180 overlaps the first source/drain contact 170 in the third direction D3, and the rest of the first contact connecting via 180 may not overlap the first source/drain contact 170 in the third direction D3.

Unlike the shown example, the entire first contact connecting via 180 may not overlap the first source/drain contact 170 in the third direction D3. The first contact connecting via 180 and the first source/drain contact 170 may be electrically connected by a connecting conductive pattern on the first upper interlayer insulating film 190.

The first contact connecting via 180 may be disposed in the first upper interlayer insulating film 190 and the field insulating film 105. A part of the first contact connecting via 180 may be disposed in the field insulating film 105.

A height of the lowermost part of the first contact connecting via 180 from the second side 100BS of the substrate may be the same as the thickness of the substrate 100.

A first connecting via silicide film 185 may be disposed between the first contact connecting via 180 and the first buried conductive pattern 70. A second connecting via silicide film 285 may be disposed between the second contact connecting via 280 and the first buried conductive pattern 70. A third connecting via silicide film 385 may be disposed between the third contact connecting via 380 and the second buried conductive pattern 80. A fourth connecting via silicide film 485 may be disposed between the fourth contact connecting via 480 and the second buried conductive pattern 80.

A connecting via liner 181 may be disposed on the side walls of the first contact connecting via 180 and the side walls of the second contact connecting via 280. The connecting via liner 181 may be disposed on the side walls of the third contact connecting via 380 and the side walls of the fourth contact connecting via 480. Unlike the shown example, the connecting via liner may not be disposed on the side walls of the contact connecting vias 180, 280, 380 and 480.

Although the contact connecting vias 180, 280, 380 and 480 are shown to have a single conductive film structure, example embodiments are not limited thereto. The contact connecting vias 180, 280, 380 and 480 may have multiple conductive film structures. The contact connecting vias 180, 280, 380 and 480 may include, for example, at least one of metal, conductive metal nitride, conductive metal carbide, conductive metal oxide, conductive metal carbonitride, and a two-dimensional material. Each of the contact via silicide films 185, 285, 385 and 485 may include a metal silicide material.

The connecting via liner 181 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

The second upper interlayer insulating film 191 may be disposed on the first upper interlayer insulating film 190, the first gate structure GS1, the second gate structure GS2, the source/drain contacts 170, 270, 370 and 470, and the contact connecting vias 180, 280, 380 and 480. The second upper interlayer insulating film 191 may include, for example, at least one of silicon oxide, silicon nitride, silicon oxynitride, and a low dielectric constant material.

The front wiring structure 195 may be disposed in the second interlayer insulating film 191. The front wiring structure 195 is disposed on the first side 100US of the substrate. The front wiring structure 195 may include a front wiring via 196 and a front wiring line 197.

The front wiring structure 195 may be connected to the source/drain contacts 170, 270, 370 and 470, the connecting source/drain contacts 172 and 272, and the gate contacts 175 and 275.

The front wiring via 196 and the front wiring line 197 may each include, for example, at least one of a metal, conductive metal nitride, conductive metal carbide, conductive metal oxide, conductive metal carbonitride, and a two-dimensional material.

Although the front wiring via 196 and the front wiring line 197 are each shown as being a single conductive film structure, example embodiments are not limited thereto. Unlike the shown example, as an example, at least one of the front wiring via 196 and the front wiring line 197 may have multiple conductive film structures. As another example, the front wiring structure 195 may have an integrated structure with no boundary division between the front wiring via 196 and the front wiring line 197.

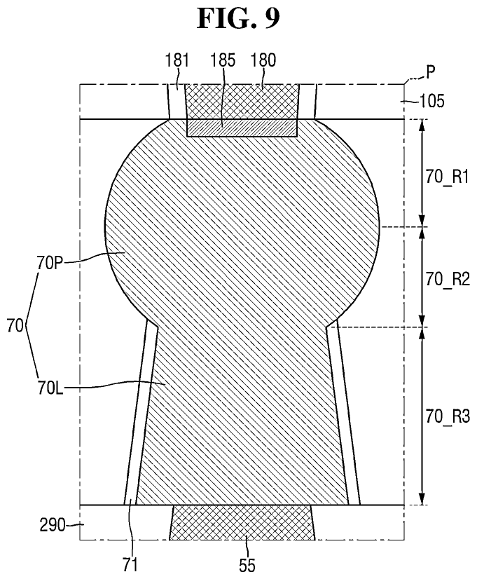

FIGS. 9 to 17 are diagrams for explaining a semiconductor device according to some example embodiments, respectively. For convenience of explanation, the explanation will be provided mainly on points that are different from those explained using FIGS. 1 to 8. For reference, FIGS. 9 to 17 are enlarged views of a portion P of FIG. 4.

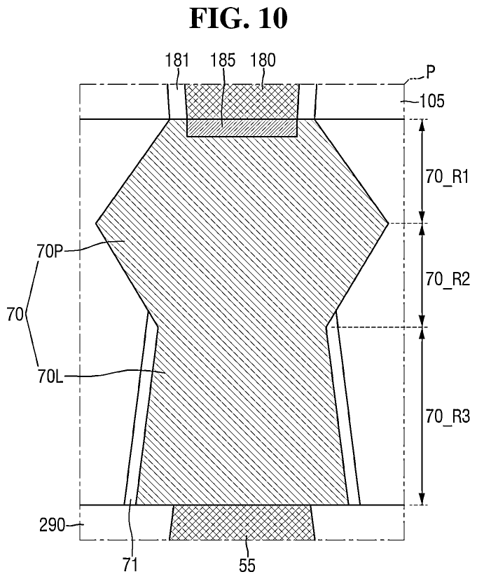

Referring to FIGS. 9 and 10, in the semiconductor device according to some example embodiments, at the first portion 70_R1 of the first buried conductive pattern, the width the second direction D2 of the first buried conductive pattern 70 in may decrease, as it goes away from the first back wiring line 50.

At the first buried conductive protrusion 70P, the width in the second direction D2 of the first buried conductive pattern 70 may increase and then decrease, as it goes away from the first back wiring line 50.

In FIG. 9, the side walls of the first buried conductive protrusion 70P may have curved surfaces in terms of a cross-sectional view. For example, the first buried conductive protrusion 70P may have a circular (spherical) or elliptical ball shape.

In FIG. 10, in terms of a cross-sectional view, the side walls of the first buried conductive protrusion 70 may have a shape in which inclined surfaces having different marks are connected to each other. For example, the first buried conductive protrusion 70 may have a shape similar to a hexagon. A thickness of the first portion 70_R1 may be the same as, or different from, a thickness of the second portion 70_R2.

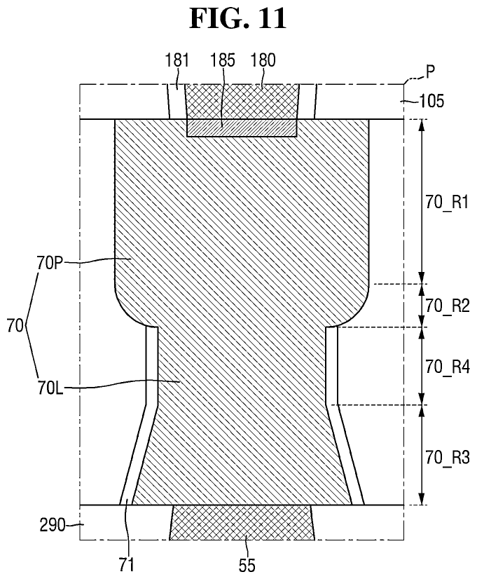

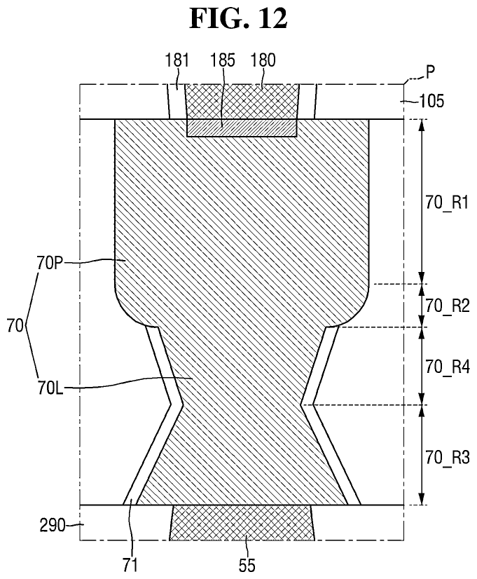

Referring to FIGS. 11 and 12, in the semiconductor device according to some example embodiments, the first buried conductive pattern 70 may further include a fourth portion 70_R4 that is disposed between the second portion 70_R2 of the first buried conductive pattern and the third portion 70_R3 of the first buried conductive pattern.

For example, the fourth portion 70_R4 of the first buried conductive pattern may be included in the first buried conductive line 70L.

In FIG. 11, at the fourth portion 70_R4 of the first buried conductive pattern, the width in the second direction D2 of the first buried conductive pattern 70 may be constant as it goes away from the first back wiring line 50. At the first buried conductive line 70L, the width in the second direction D2 of the first buried conductive pattern 70 may decrease and then be kept constant, as it goes away from the first back wiring line 50.

In FIG. 12, at the fourth portion 70_R4 of the first buried conductive pattern, the width in the second direction D2 of the first buried conductive pattern 70 may increase, as it goes away from the first back wiring line 50. At the first buried conductive line 70L, the width in the second direction D2 of the first buried conductive pattern 70 may decrease and then increase, as it goes away from the first back wiring line 50. The shape or slope of the side wall of the first buried conductive pattern 70 may change between the second portion 70_R2 of the first buried conductive pattern and the fourth portion 70_R4 of the first buried conductive pattern.

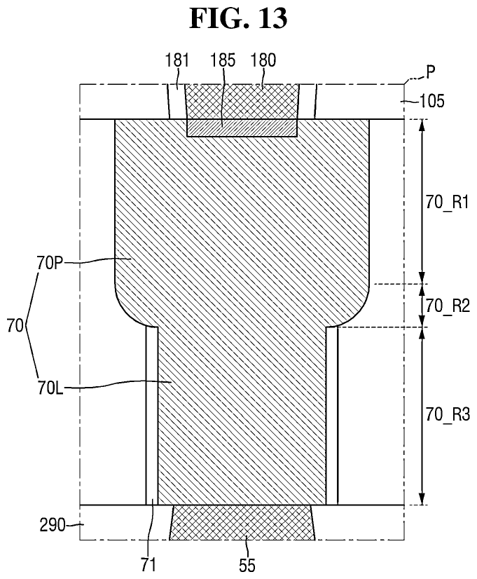

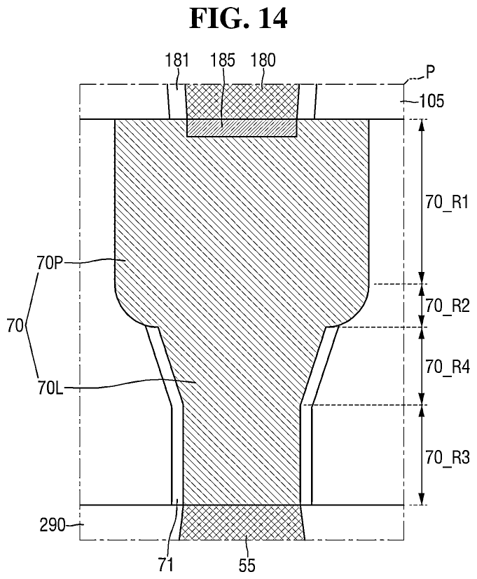

Referring to FIGS. 13 and 14, in the semiconductor device according to some example embodiments, at the third portion 70_R3 of the first buried conductive pattern, the width in the second direction D2 of the first buried conductive pattern 70 may be constant, as it goes away from the wiring line 50.

In FIG. 13, the third portion 70_R3 of the first buried conductive pattern may be directly connected to the second portion 70_R2 of the first buried conductive pattern.

In FIG. 14, the first buried conductive pattern 70 may further include a fourth portion 70_R4 that is disposed between the second portion 70_R2 of the first buried conductive pattern and the third portion 70_R3 of the first buried conductive pattern. The fourth portion 70_R4 of the first buried conductive pattern may be included in the first buried conductive line 70L. At the fourth portion 70_R4 of the first buried conductive pattern, the width in the second direction D2 of the first buried conductive pattern 70 may increase, as it goes away from the first back wiring line 50. At the first buried conductive line 70L, the width of the first buried conductive pattern 70 in the second direction D2 may be kept constant and then increase, as it goes away from the first back wiring line 50.

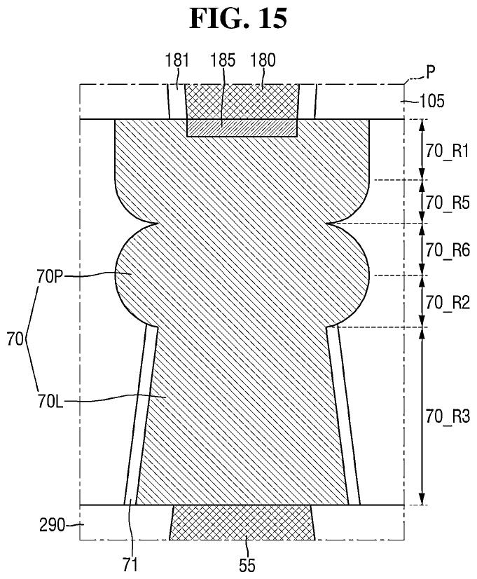

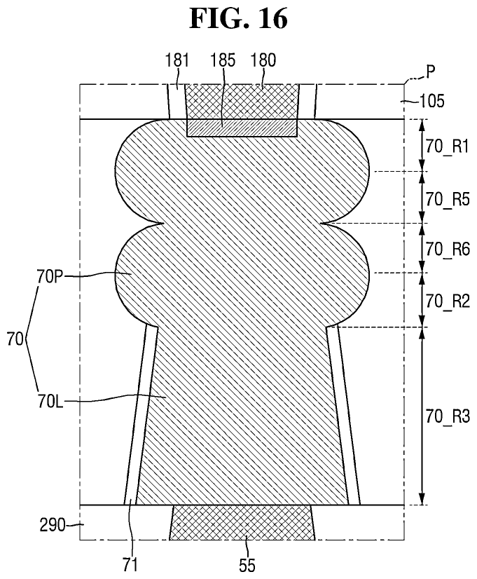

Referring to FIGS. 15 and 16, in the semiconductor device according to some example embodiments, the first buried conductive pattern 70 may further include a fifth portion 70_R5 and a sixth portion 70_R6 that are disposed between the first portion 70_R1 of the first buried conductive pattern and the second portion 70_R2 of the first buried conductive pattern.

For example, the fifth portion 70_R5 of the first buried conductive pattern and the sixth portion 70_R6 of the first buried conductive pattern may be included in the first buried conductive protrusion 70P. The sixth portion 70_R6 of the first buried conductive pattern may be disposed between the fifth portion 70_R5 of the first buried conductive pattern and the second portion 70_R2 of the first buried conductive pattern.

At the fifth portion 70_R5 of the first buried conductive pattern, the width in the second direction D2 may increase of the first buried conductive pattern 70, as it goes away from the first back wiring line 50. At the sixth portion 70_R6 of the first buried conductive pattern, the width in the second direction D2 of the first buried conductive pattern 70 may decrease, as it goes away from the first back wiring line 50.

In FIG. 15, at the first portion 70_R1 of the first buried conductive pattern, the width in the second direction D2 of the first buried conductive pattern 70 may be constant, as it goes away from the first back wiring line 50.

In FIG. 16, at the first portion 70_R1 of the first buried conductive pattern, the width in the second direction D2 of the first buried conductive pattern 70 may decrease, as it goes away from the first back wiring line 50.

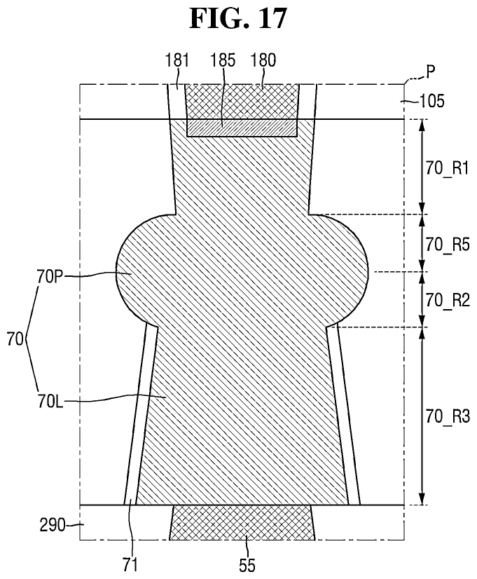

Referring now to FIG. 17, in the semiconductor device according to some example embodiments, at the first portion 70_R1 of the first buried conductive pattern, the width in the second direction D2 of the first buried conductive pattern 70 may increase, as it goes away from the first back wiring line 50.

The first buried conductive pattern 70 may further include a fifth portion 70_R5 that is disposed between the first portion 70_R1 of the first buried conductive pattern and the second portion 70_R2 of the first buried conductive pattern. At the fifth portion 70_R5 of the first buried conductive pattern, the width in the second direction D2 of the first buried conductive pattern 70 may decrease, as it goes away from the first back wiring line 50.

At the first buried conductive protrusion 70P, the width in the second direction D2 of the first buried conductive pattern 70 may increase, decrease, and then increase again, as it goes away from the first back wiring line 50.

Example embodiments are not necessarily mutually exclusive with one another. For example, some example embodiments may include one or more features from one or more of FIGS. 8 to 17, and may also include one or more other features from one or more other ones of FIGS. 8 to 17.

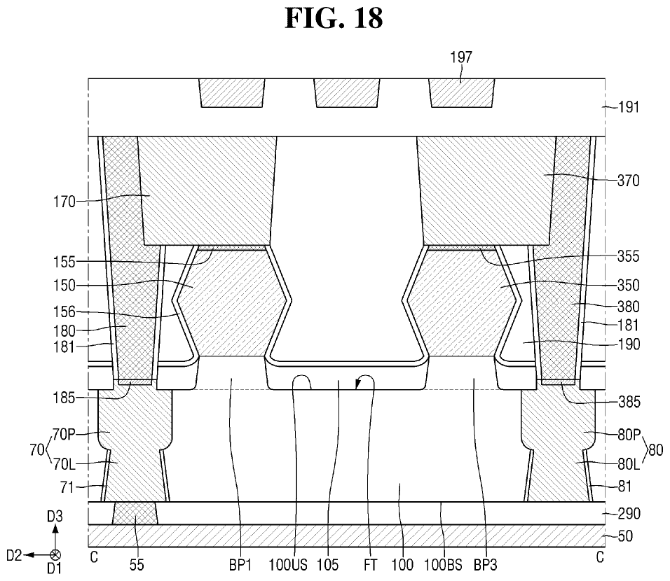

FIGS. 18 to 21 are diagrams for explaining a semiconductor device according to some example embodiments, respectively. For convenience of explanation, the explanation will be provided mainly on points that are different from those explained using FIGS. 1 to 8.

Referring to FIG. 18, in the semiconductor device according to some example embodiments, the height of the lowermost part of the first contact connecting via 180 from the second side 100BS of the substrate may be greater than the thickness of the substrate 100.

On the basis of the second side 100BS of the substrate, the lowermost part of the first contact connecting via 180 may be higher than the first side 100US of the substrate.

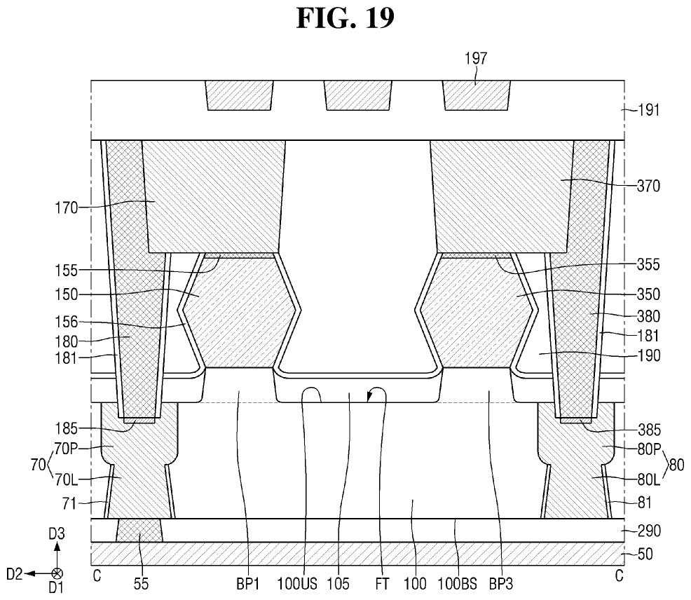

Referring to FIG. 19, in the semiconductor device according to some example embodiments, the height of the lowermost part of the first contact connecting via 180 from the second side 100BS of the substrate may be smaller than the thickness of the substrate 100.

On the basis of the second side 100BS of the substrate, the lowermost part of the first contact connecting via 180 may be lower than the first side 100US of the substrate.

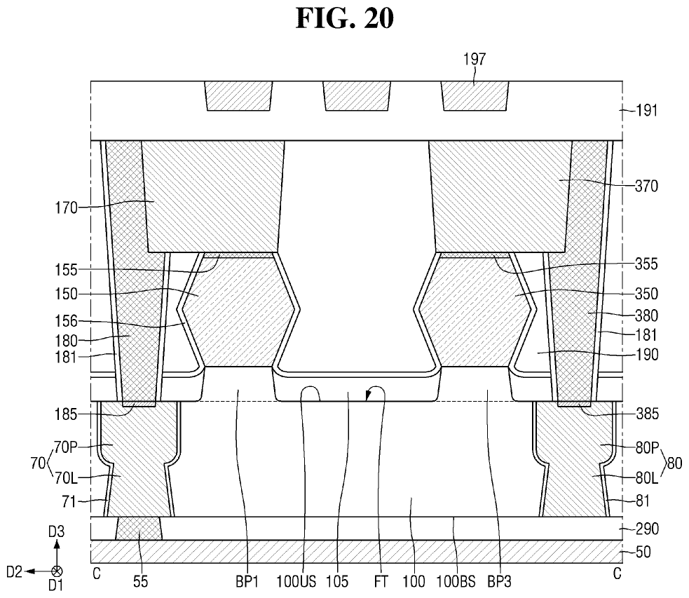

Referring to FIG. 20, in the semiconductor device according to some example embodiments, the first buried insulating liner 71 may extend along sidewalls of the first buried conductive line 70L and side walls of the first buried conductive protrusion 70P.

The second buried insulating liner 81 may extend along sidewalls of the second buried conductive line 80L and side walls of the second buried conductive protrusion 80P.

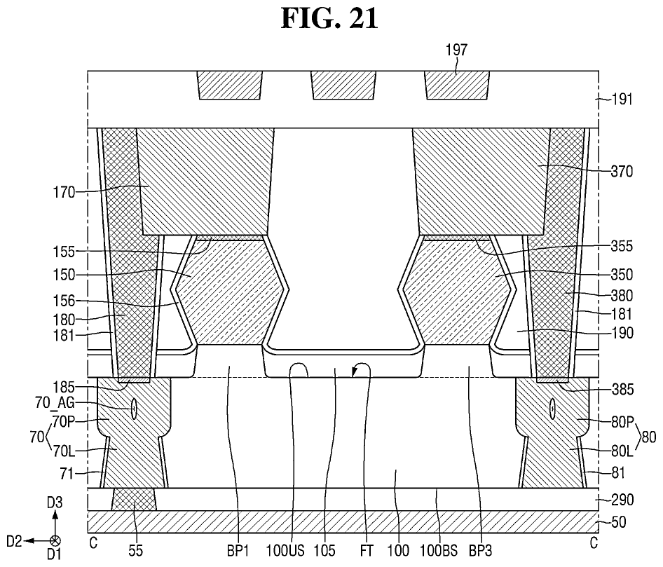

Referring to FIG. 21, in the semiconductor device according to some example embodiments, the first buried conductive pattern 70 may include a buried air gap 70_AG.

The buried air gap 70_AG may be included in the first buried conductive protrusion 70P. Unlike the shown example, the first buried conductive pattern 70 may include a scam pattern.

The second buried conductive pattern 80 may also include an air gap or a seam pattern.

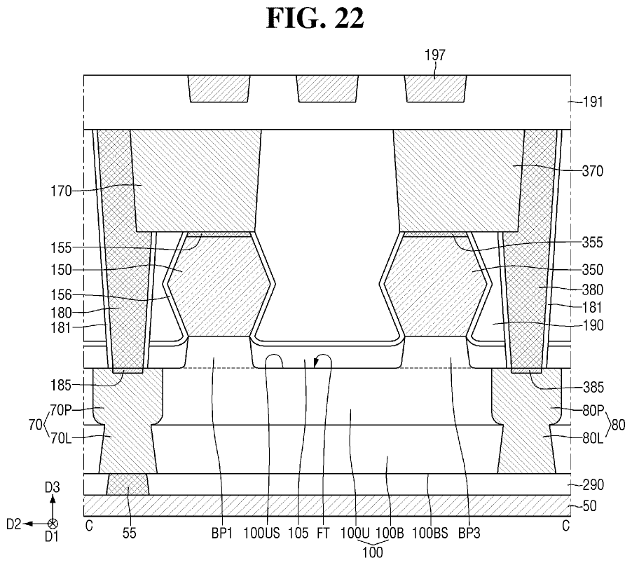

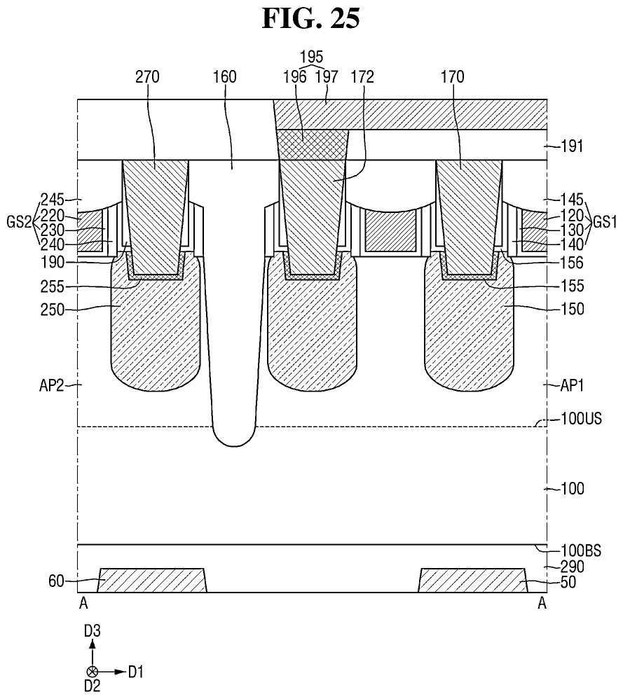

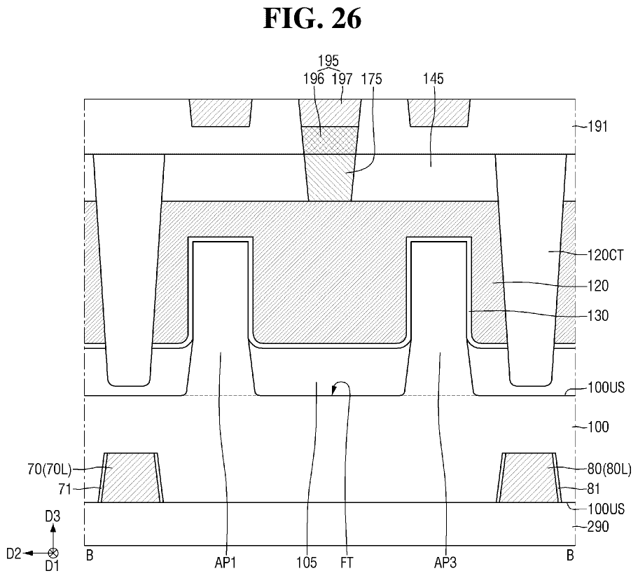

FIGS. 22 to 24 are diagrams for explaining a semiconductor device according to some example embodiments, respectively. FIGS. 25 and 26 are diagrams for explaining a semiconductor device according to some example embodiments. For convenience of explanation, the explanation will be provided mainly on points that are different from those explained using FIGS. 1 to 8.

Referring to FIG. 22, in the semiconductor device according to some example embodiments, the substrate 100 may include a lower substrate 100B and an upper substrate 100U.

The lower substrate 100B includes a second side 100BS of the substrate. The upper substrate 100U includes a first side 100US of the substrate. The lower substrate 100B may be an insulating substrate including an insulating material. The upper substrate 100U may be a semiconductor substrate.

For example, the first buried conductive line 70L and the second buried conductive line 80L may be disposed in the lower substrate 100B. The first buried conductive protrusion 70P and the second buried conductive protrusion 80P may be disposed in the upper substrate 100U.

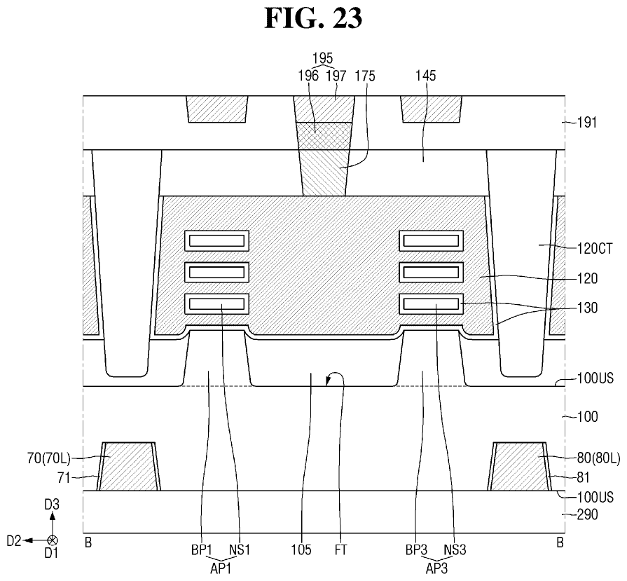

Referring to FIG. 23, in the semiconductor device according to some example embodiments, a first gate insulating film 130 may be disposed between the first gate electrode 120 and the gate isolation structure 120CT.

The first gate insulating film 130 may extend in the third direction D3 along the short side wall of the first gate electrode 120.

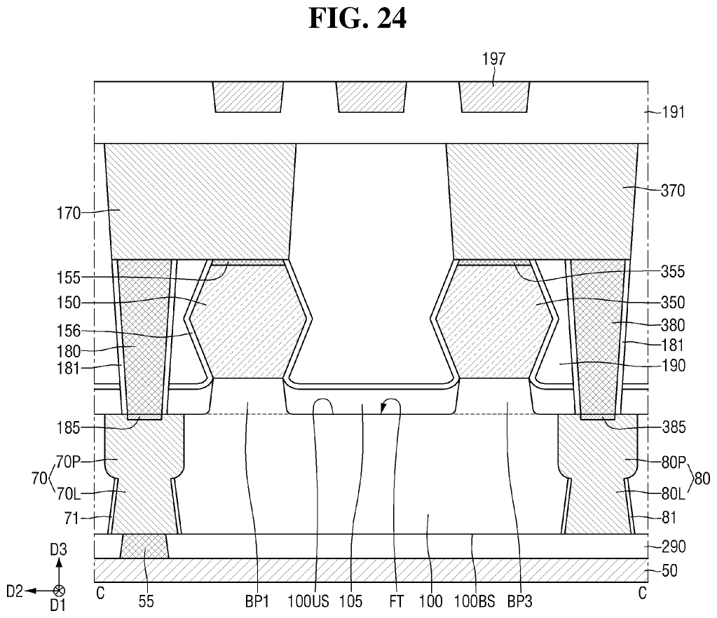

Referring to FIG. 24, the first source/drain contact 170 may cover the entire first contact connecting via 180.

The entire first contact connecting via 180 may overlap the first source/drain contact 170 in the third direction D3. In terms of a cross-sectional view, the first source/drain contact 170 may cover the entire upper surface of the first contact connecting via 180.

The shape of the first contact connecting via 180 may be applied to the second to fourth contact connecting vias 280, 380 and 480.

Referring to FIGS. 25 and 26, in the semiconductor device according to some example embodiments, active patterns AP1, AP2, AP3, and AP4 each do not include a sheet pattern.

The active patterns AP1, AP2, AP3 and AP4 may be fin-shaped patterns protruding upward from the upper surface of the field insulating film 105. In FIG. 26, the field insulating film 105 may partially cover side walls of the active patterns AP1, AP2, AP3 and AP4.

The first gate structure GS1 does not include the first inner gate structure INT_GS1. The second gate structure GS2 does not include the second inner gate structure INT_GS2.

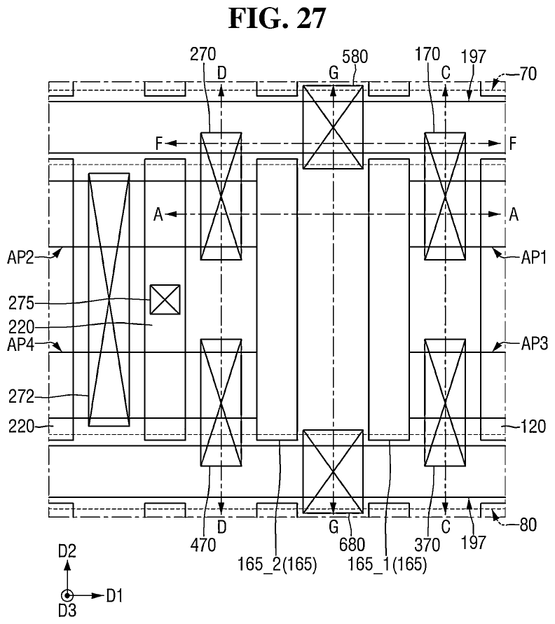

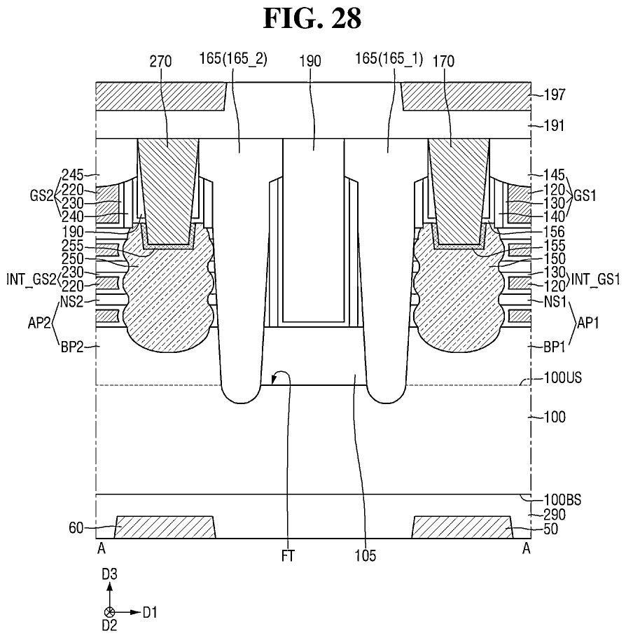

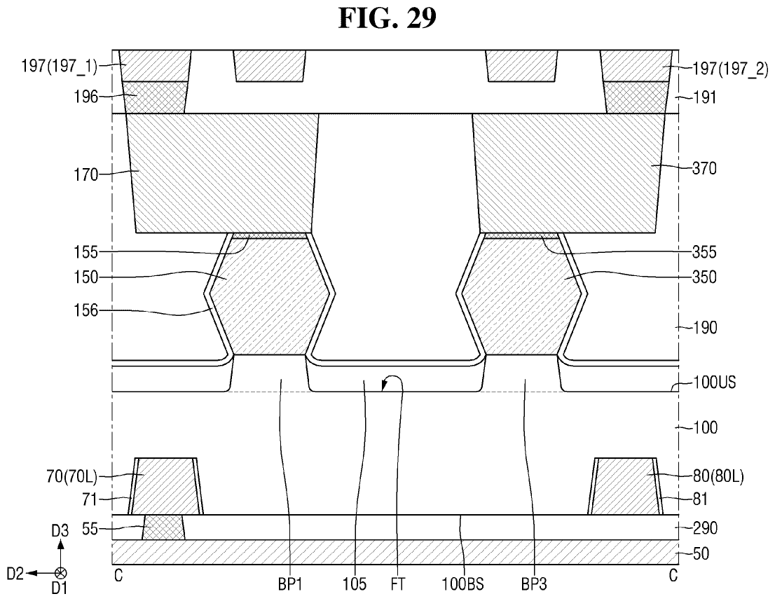

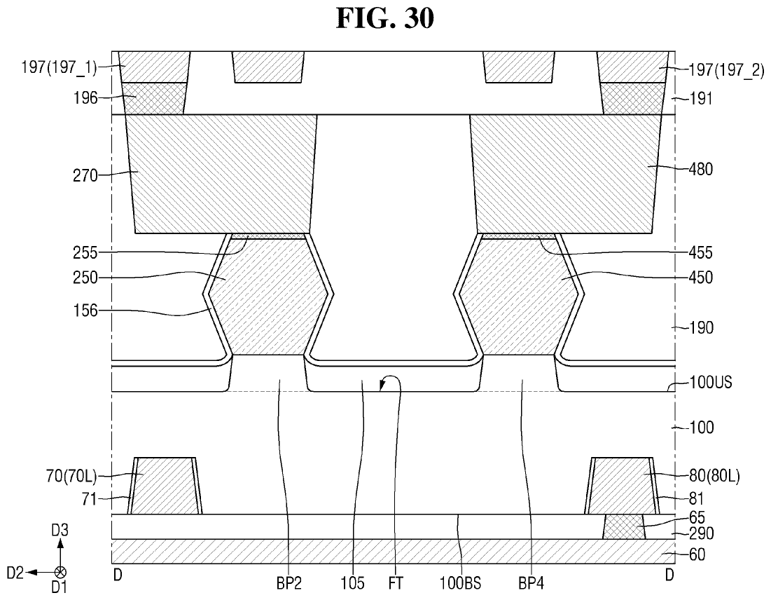

FIG. 27 is a layout diagram for explaining a semiconductor device according to some example embodiments. FIGS. 28 to 32 are cross-sectional views taken along A-A, C-C, D-D. F-F and G-G of FIG. 27. For convenience of explanation, the explanation will be provided mainly on points that are different from those explained using FIGS. 1 to 8.

Referring to FIGS. 27 to 32, in the semiconductor device according to some example embodiments, the pair of second element isolation structures 165 may be disposed between the first active pattern AP1 and the second active pattern AP2, and between the third active pattern AP3 and the fourth active pattern AP4.

A pair of second element isolation structures 165 may be disposed on the substrate 100. The second element isolation structure 165 may be disposed on the first side 100US of the substrate.

The pair of second element isolation structures 165 may include a first sub-element isolation structure 165_1 and a second sub-element isolation structure 165_2. The first sub-element isolation structure 165_1 and the second sub-element isolation structure 165_2 may each extend in the second direction D2. The first sub-element isolation structure 165_1 may be spaced apart from the second sub-element isolation structure 165_2 in the first direction D1.

The second element isolation structure 165 may separate the first lower pattern BP1 and the second lower pattern BP2. The second element isolation structure 165 may isolate the third lower pattern BP3 and the fourth lower pattern BP4. The first active pattern AP1 and the second active pattern AP2 are not disposed between the first sub-element isolation structure 165_1 and the second sub-element isolation structure 165_2. For example, the first lower pattern BP1 and the second lower pattern BP2 are not disposed between the first sub-element isolation structure 165_1 and the second sub-element isolation structure 165_2. A part of the field insulating film 105 may be disposed between the first sub-element isolation structure 165_1 and the second sub-element isolation structure 165_2 adjacent in the first direction D1.

Unlike the shown example, a dummy active pattern including a semiconductor material may be disposed between the first sub-element isolation structure 165_1 and the second sub-element isolation structure 165_2. The dummy active pattern may not be electrically active during operation of the semiconductor device.

The first lower pattern BP1 may protrude from the first sub-element isolation structure 165_1 in the first direction D1. The second lower pattern BP2 may protrude from the second sub-element isolation structure 165_2 in the first direction D1. Although not shown, the third lower pattern BP3 may protrude from the first sub-element isolation structure 165_1 in the first direction D1. The fourth lower pattern BP4 may protrude from the second sub-element isolation structure 165_2 in the first direction D1.

The height of the upper surface of the first sub-element isolation structure 165_1 may be equal to the height of the upper surface of the first gate capping pattern 145 on the basis of the second side 100BS of the substrate. Unlike the shown example, the upper surface of the first sub-element isolation structure 165_1 may be higher than the upper surface of the first gate capping pattern 145, on the basis of the second side 100BS of the substrate.

The second element isolation structure 165 may include an insulating material. Although the first sub-element isolation structure 165_1 and the second sub-element isolation structure 165_2 are shown as single films, example embodiments are not limited thereto.

A first upper interlayer insulating film 190 and a source/drain etching stop film 156 may be disposed between the first sub-element isolation structure 165_1 and the second sub-element isolation structure 165_2. For example, an insulating spacer pattern that is in contact with the source/drain etching stop film 156 may be disposed between the first sub-element isolation structure 165_1 and the source/drain etching stop film 156. The insulating spacer pattern may include the same material as the first gate spacer 140.

A fifth contact connecting via 580 may be disposed between the first sub-element isolation structure 165_1 and the second sub-element isolation structure 165_2. A fifth contact connecting via 580 may connect the first buried conductive pattern 70 and the first source/drain contact 170. A fifth contact connecting via 580 may connect the first buried conductive pattern 70 and the second source/drain contact 270. The fifth contact connecting via 580 may be connected to the first back wiring line 50.

The fifth contact connecting via 580 does not overlap the first source/drain contact 170 in the second direction D2. The fifth contact connecting via 580 does not overlap the second source/drain contact 270 in the second direction D2. The fifth contact connecting via 580 may be spaced apart from the first source/drain contact 170 in the first direction D1. The fifth contact connecting via 580 may be spaced apart from the second source/drain contact 270 in the first direction D1.

A sixth contact connecting via 680 may be disposed between the first sub-element isolation structure 165_1 and the second sub-element isolation structure 165_2. The sixth contact connecting via 680 may connect the second buried conductive pattern 80 and the third source/drain contact 370. The sixth contact connecting via 680 may connect the second buried conductive pattern 80 and the fourth source/drain contact 470. The sixth contact connecting via 680 may be connected to the second back wiring line 60.

The sixth contact connecting via 680 does not overlap the third source/drain contact 370 in the second direction D2. The sixth contact connecting via 680 does not overlap the fourth source/drain contact 470 in the second direction D2. The sixth contact connecting via 680 may be spaced apart from the third source/drain contact 370 in the first direction D1. The sixth contact connecting via 680 may be spaced apart from the fourth source/drain contact 470 in the first direction D1.

The fifth contact connecting via 580 passes through the source/drain etching stop film 156, and may be connected to the first buried conductive protrusion 70P. The sixth contact connecting via 680 passes through the source/drain etching stop film 156, and may be connected to the second buried conductive protrusion 80P. The fifth contact connecting via 580 may be spaced apart from the sixth contact connecting via 680 in the second direction D2. The fifth contact connecting via 580 and the sixth contact connecting via 680 may be arranged in the second direction D2.

The width of the fifth contact connecting via 580 in the first direction D1 may increase, as it goes away from the first back wiring line 50. The width of the fifth contact connecting via 580 in the second direction D2 may increase, as it goes away from the first back wiring line 50. The description regarding the width of the sixth contact connecting via 680 may be substantially the same as the description regarding the width of the fifth contact connecting via 580.

A fifth connecting via silicide film 585 may be disposed between the fifth contact connecting via 580 and the first buried conductive pattern 70. A sixth connecting via silicide film 685 may be disposed between the sixth contact connecting via 680 and the second buried conductive pattern 80.

The front wiring structure 195 may further include a wiring connecting via 198 that connects the front wiring line 197 and the contact connecting vias 580 and 680. The front wiring line 197 may include a first front wiring line 197_1 and a second front wiring line 197_2. The first front wiring line 197_1 and the second front wiring line 197_2 may each extend long in the first direction D1.

The first front wiring line 197_1 may connect the first source/drain contact 170 and the fifth contact connecting via 580. The first front wiring line 197_1 may connect the second source/drain contact 270 and the fifth contact connecting via 580.

The second front wiring line 197_2 may connect the third source/drain contact 370 and the sixth contact connecting via 680. The second front wiring line 197_2 may connect the fourth source/drain contact 470 and the sixth contact connecting via 680.

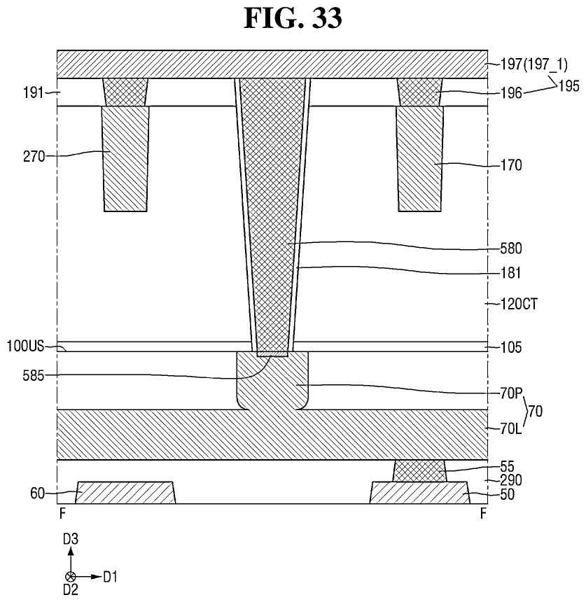

FIG. 33 is a diagram for explaining a semiconductor device according to some example embodiments. For convenience of explanation, the explanation will be provided mainly on points that are different from those explained using FIGS. 27 to 33.

Referring to FIG. 33, in the semiconductor device according to some example embodiments, the first front wiring line 197_1 may be directly connected to the fifth contact connecting via 580.

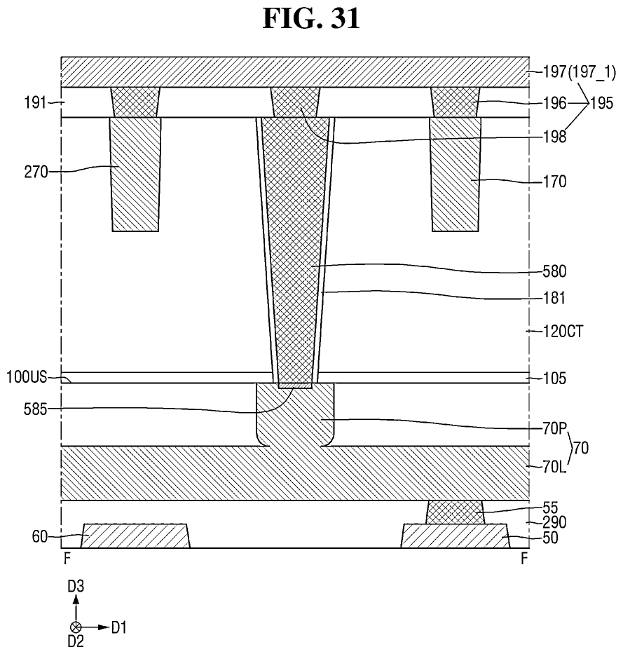

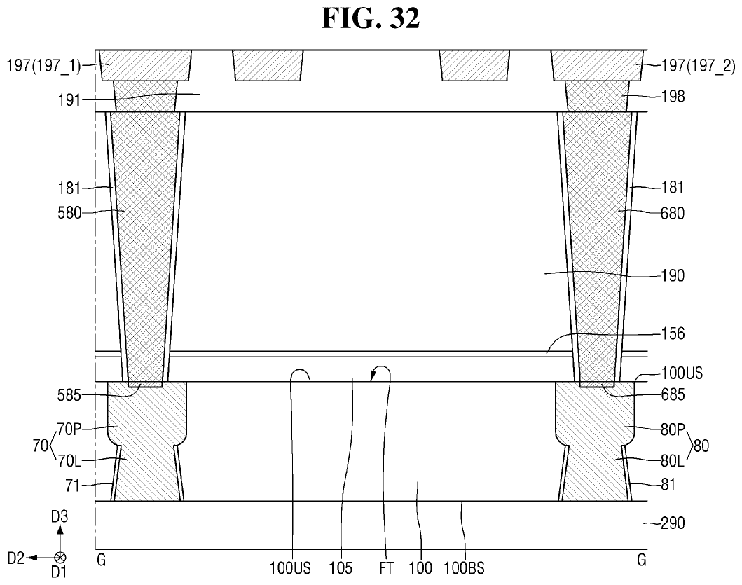

The fifth contact connecting via 580 may be connected to the first front wiring line 197_1 without the wiring connecting via (198 of FIGS. 31 and 32).

Although not shown, the second front wiring line (197_2 of FIGS. 31 and 32) may be directly connected to the second contact connecting via (280 of FIGS. 31 and 32).

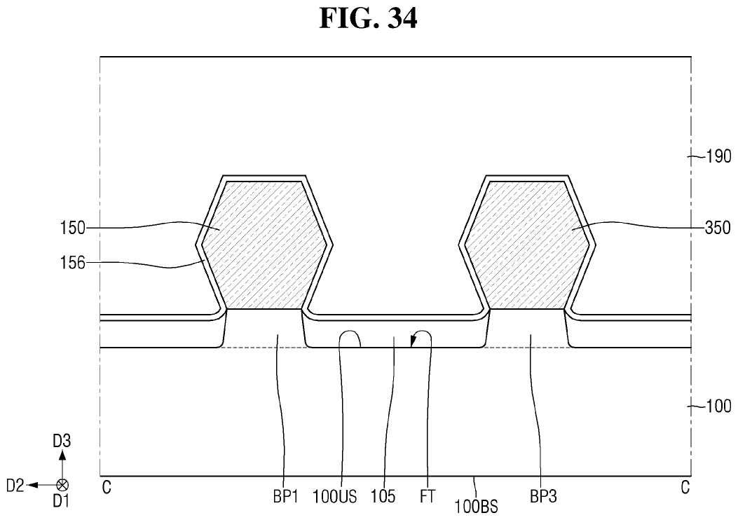

FIGS. 34 to 41 are intermediate step diagrams for describing a method for fabricating the semiconductor device according to various example embodiments. Any one or more of the semiconductor device described using FIGS. 1 to 24 may be fabricated or at least partly fabricated, by referring to FIGS. 34 to 41.

Referring to FIG. 34, the first source/drain pattern 150 is formed on the first lower pattern BP1. The third source/drain pattern 350 is formed on the third lower pattern BP3. The first lower pattern BP1 and the third lower pattern BP3 may protrude from the substrate 100.

The source/drain etching stop film 156 is formed along profiles of the first source/drain pattern 150 and the third source/drain pattern 350. The source/drain etching stop film 156 is formed along the upper surface of the field insulating film 105. The first upper interlayer insulating film 190 is formed on the source/drain etching stop film 156.

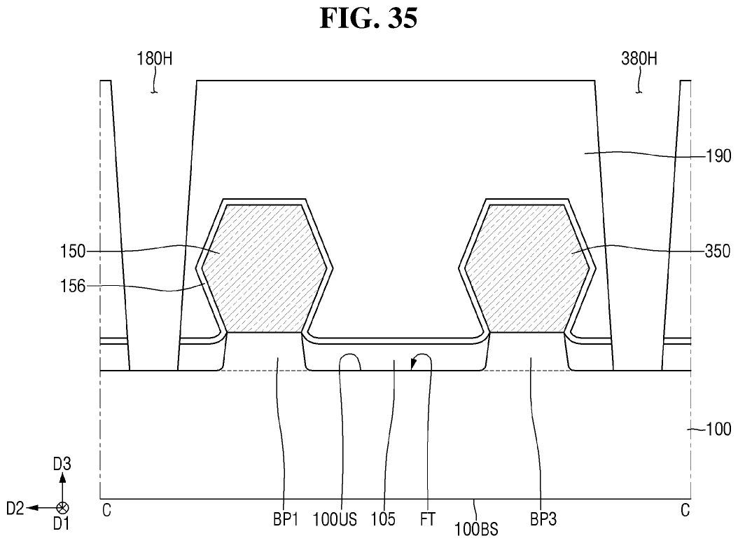

Referring to FIG. 35, a first contact via hole 180H and a second contact via hole 380H are formed in the first upper interlayer insulating film 190.

The first contact via hole 180H and the second contact via hole 380H may penetrate the source/drain etching stop film 156 and the field insulating film 105 to expose the substrate 100. Either or both of the first contact via hole 170H and the second contact via hole 380 may be etched, e.g., anisotropically etched, and may have a tapered profile.

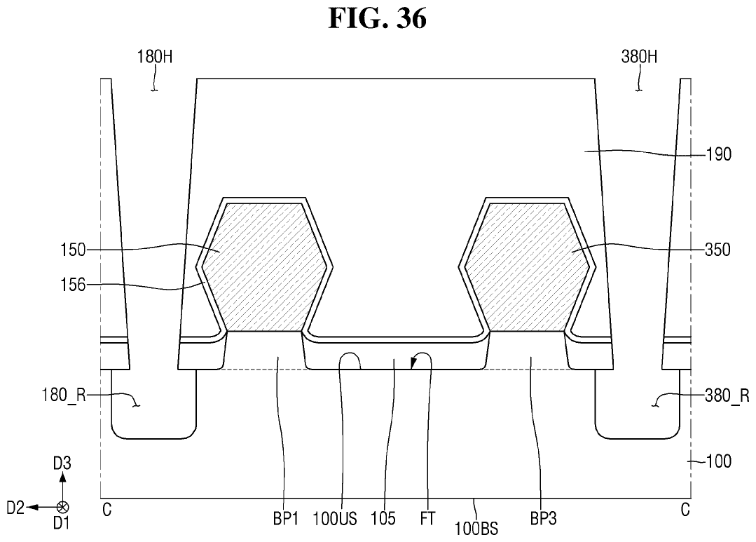

Referring to FIG. 36, a part of the substrate 100 exposed by the first contact via hole 180H may be removed, e.g., isotropically removed, to form a first contact recess 180_R in the substrate 100.

A part of the substrate 100 exposed by the second contact via hole 380H may be removed to form a second contact recess 380_R in the substrate 100.

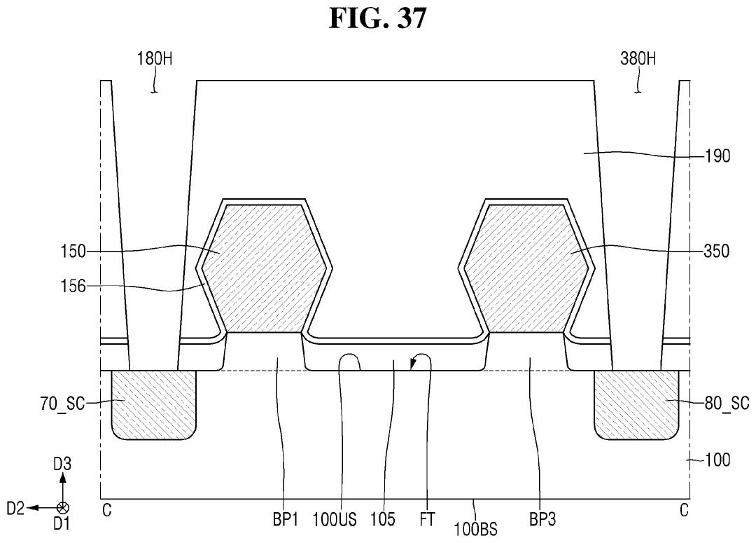

Referring to FIGS. 36 and 37, a first sacrificial semiconductor pattern 70_SC and a second sacrificial semiconductor pattern 80_SC may be formed in the substrate 100.

The first sacrificial semiconductor pattern 70_SC may fill the first contact recess 180_R. The second sacrificial semiconductor pattern 80_SC may fill the second contact recess 380_R.

The first sacrificial semiconductor pattern 70_SC and the second sacrificial semiconductor pattern 80_SC may be formed using, for example, an epitaxial growth method such as but not limited to a chemical vapor deposition (CVD) process for epitaxial growth. The first sacrificial semiconductor pattern 70_SC and the second sacrificial semiconductor pattern 80_SC may include a semiconductor material having an etching selectivity with respect to the substrate 100. When the substrate 100 is a silicon substrate, the first sacrificial semiconductor pattern 70_SC and the second sacrificial semiconductor pattern 80_SC may include, for example, silicon germanium.

The widths of the first sacrificial semiconductor pattern 70_SC and the second sacrificial semiconductor pattern 80_SC are greater than the widths of the contact via holes 180H and 380H on the first side 100US of the substrate.

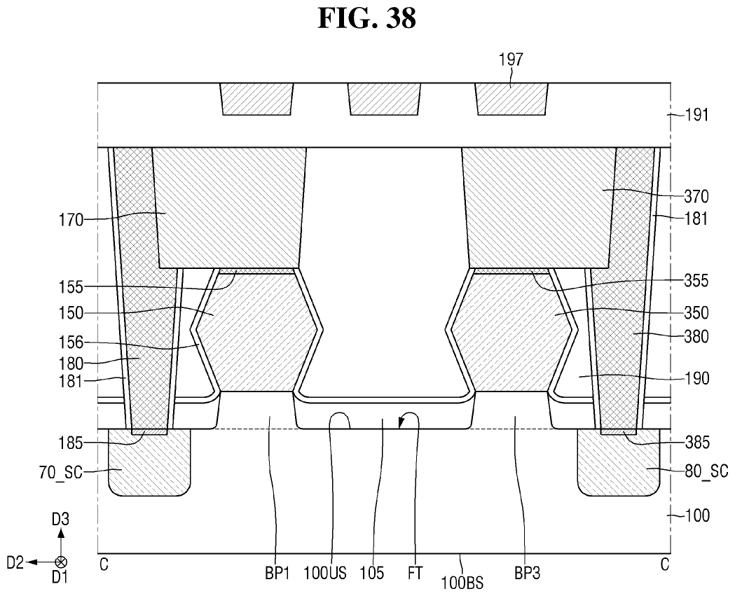

Referring to FIG. 38, the first contact connecting via 180 is formed on the first sacrificial semiconductor pattern 70_SC. The third contact connecting via 380 is formed on the second sacrificial semiconductor pattern 80_SC.

The first contact connecting via 180 may fill the first contact via hole 180H. The third contact connecting via 380 may fill the second contact via hole 380H.

Before the first contact connecting via 180 and the third contact connecting via 380 are formed, the connecting via liner 181 may be formed, e.g., conformally formed, along side walls of the contact via holes 180H and 380H. The first connecting via silicide film 185 and the third connecting via silicide film 385 may be formed, while the first contact connecting via 180 and the third contact connecting via 380 are being formed.

The width of the first sacrificial semiconductor pattern 70_SC is greater than the width of the lowermost part of the first contact connecting via 180. The width of the second sacrificial semiconductor pattern 80_SC is greater than the width of the lowermost part of the third contact connecting via 380.

Next, the first source/drain contact 170 and the third source/drain contact 370 may be formed in the first upper interlayer insulating film 190.

The second upper interlayer insulating film 191 may be formed on the first upper interlayer insulating film 190 and the source/drain contacts 170 and 370. The front wiring line 197 may be formed in the second upper interlayer insulating film 191.

Thereafter, although not shown, a part of the substrate 100 may be removed, such as by backgrinding and/or lapping, to reduce the thickness of the substrate 100.

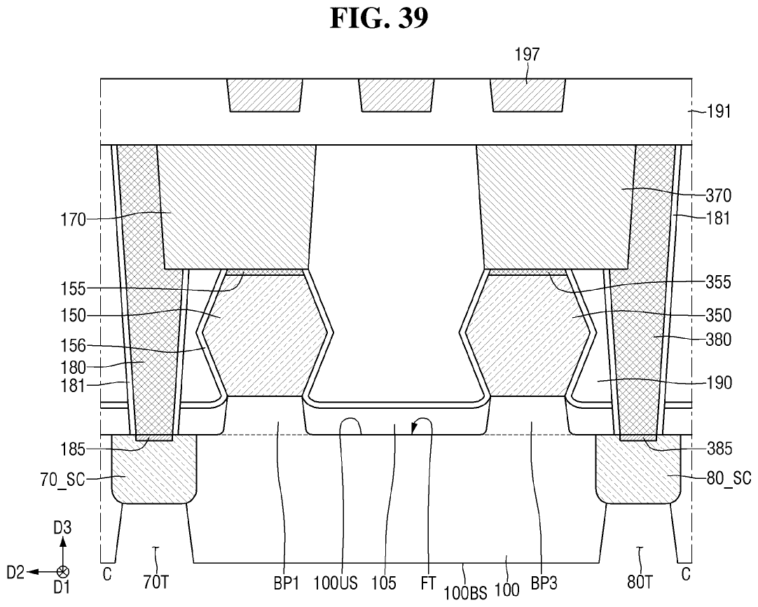

Referring to FIG. 39, a first buried trench 70T and a second buried trench 80T may be formed in the substrate 100. In some example embodiments, the semiconductor device may have a passivation protective surface (not shown) on top of the front wiring line 197 and the second upper interlayer insulating film 191, and the semiconductor device may be flipped prior to forming the first buried trench 170T and the second buried trench 180T.

The first buried trench 70T and the second buried trench 80T may extend in the first direction D1.

The first buried trench 70T exposes the first sacrificial semiconductor pattern 70_SC. The second buried trench 80T exposes the second sacrificial semiconductor pattern 80_SC.

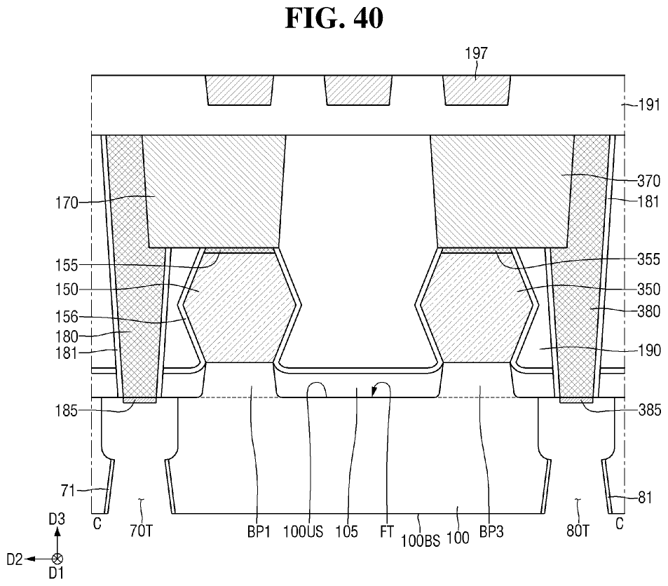

Referring to FIGS. 39 and 40, the first sacrificial semiconductor pattern 70_SC exposed by the first buried trench 70T may be removed.

The second sacrificial semiconductor pattern 80_SC exposed by the second buried trench 80T may be removed.

The first buried insulating liner 71 and the second buried insulating liner 81 may be formed, e.g., conformally formed, before the first sacrificial semiconductor pattern 70_SC and the second sacrificial semiconductor pattern 80_SC are removed.

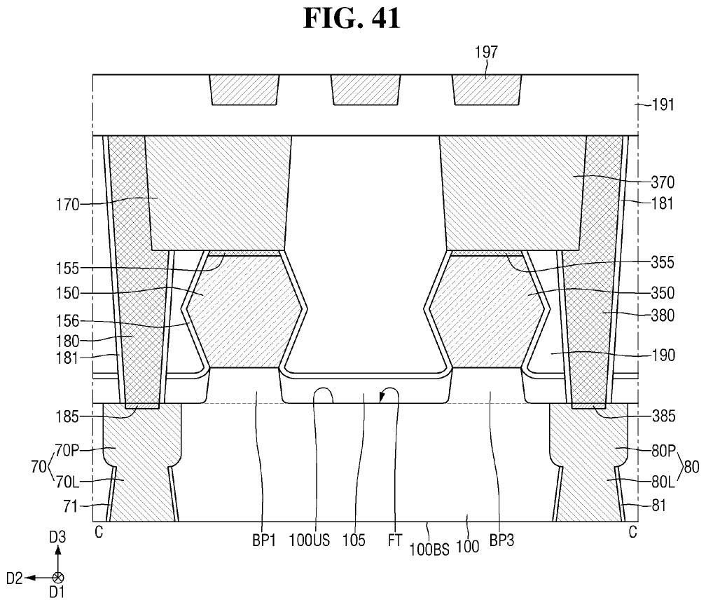

Referring to FIGS. 40 and 41, the first buried conductive pattern 70 is formed in the first buried trench 70T. The first buried conductive pattern 70 is connected to the first contact connecting via 180.

The second buried conductive pattern 80 is formed in the second buried trench 80T. The first buried conductive pattern 70 is connected to the first contact connecting via 180.

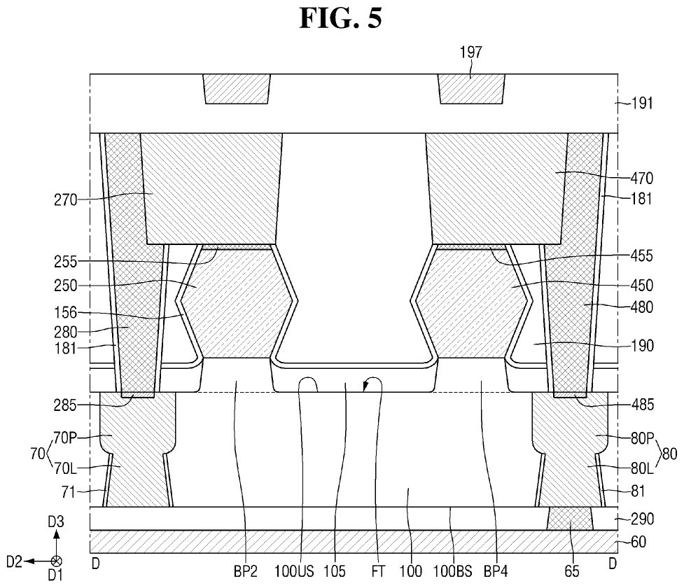

Next, referring back to FIGS. 4 and 5, the first back wiring line 50 and the second back wiring line 60 are formed in the lower interlayer insulating film 290.

In FIGS. 39 to 41, since the first buried trench 70T exposes the first sacrificial semiconductor pattern 70_SC having a width greater than that of the first contact connecting via 180, a misalignment between the first buried trench 70T and the first sacrificial semiconductor pattern 70_SC may decrease. In such a case, since a contact area between the first buried conductive pattern 70 and the first contact connecting via 180 is ensured or more likely to be ensured, the resistance of the first buried conductive pattern 70 and the first contact connecting via 180 may decrease, and a performance may be improved.

Meanwhile, the first contact connecting via 180 may be formed without the first sacrificial semiconductor pattern 70_SC. In such a case, since the first buried trench 70T needs to expose the first contact connecting via 180 having a narrow width, the misalignment between the first buried trench 70T and the first contact connecting via 180 may increase. When the misalignment between the first buried trench 70T and the first contact connecting via 180 increases, the contact area between the first buried conductive pattern 70 and the first contact connecting via 180 decreases, and the resistance between the first buried conductive pattern 70 and the first contact connecting via 180 may increase. The performance and/or reliability of the semiconductor device may be degraded, accordingly.

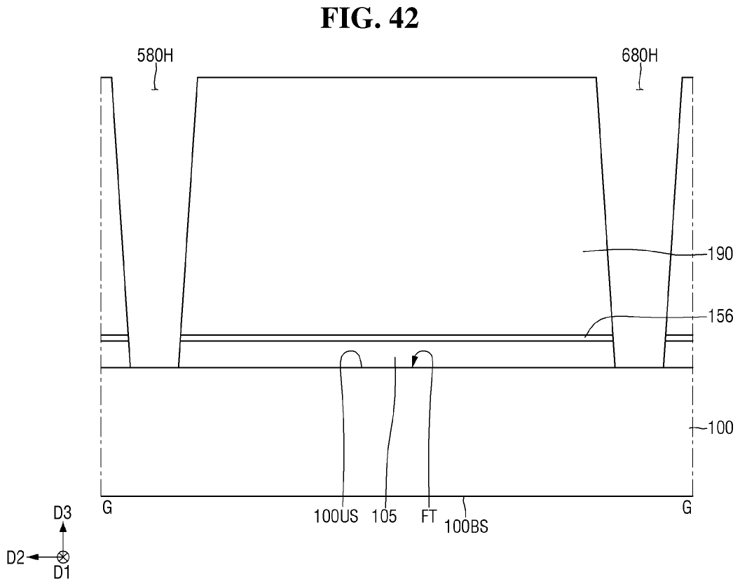

FIGS. 42 to 46 are intermediate step diagrams for describing a method for fabricating the semiconductor device according to some example embodiments. The semiconductor device described using FIGS. 27 to 33 may be fabricated, using FIGS. 42 to 46.

Referring to FIGS. 27 and 42, a third contact via hole 580H and a fourth contact via hole 680H may be formed between the first sub-element isolation structure 165_1 and the second sub-element isolation structure 165_2.

The third contact via hole 580H and the fourth contact via hole 680H may penetrate the source/drain etching stop film 156 and the field insulating film 105 to expose the substrate 100.

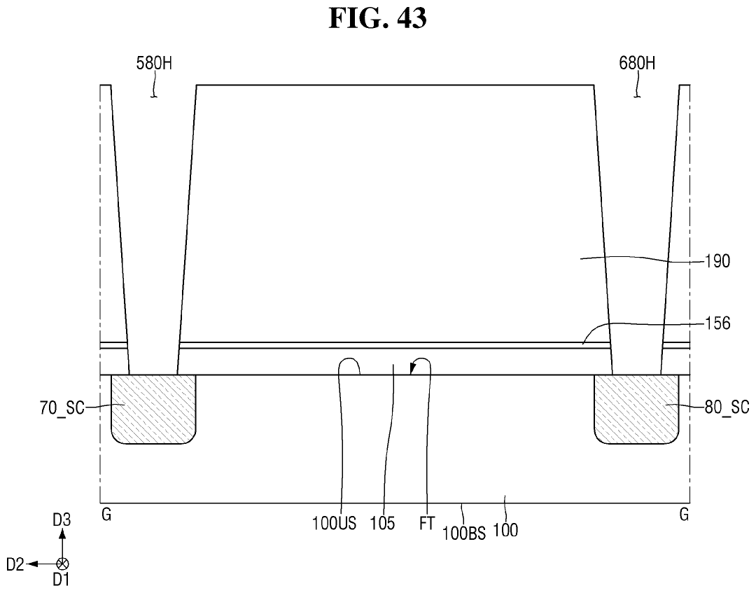

Referring to FIG. 43, a contact recess may be formed in the substrate 100, by removing a part of the substrate 100 exposed by the third contact via hole 580H and the fourth contact via hole 680H.

Next, the first sacrificial semiconductor pattern 70_SC and the second sacrificial semiconductor pattern 80_SC that fill the contact recess may be formed inside the substrate 100. The first sacrificial semiconductor pattern 70_SC may be exposed by the third contact via hole 580H. The second sacrificial semiconductor pattern 80_SC may be exposed by the fourth contact via hole 680H.

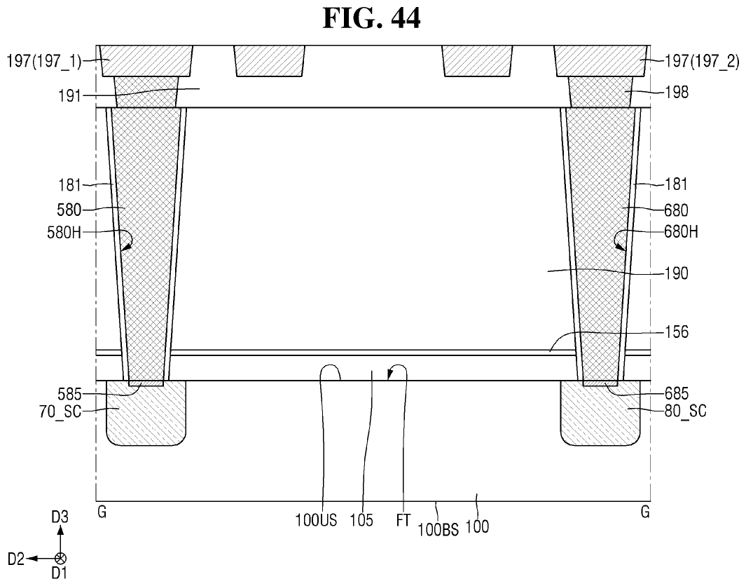

Referring to FIG. 44, a first contact connecting via 580 is formed on the first sacrificial semiconductor pattern 70_SC. A sixth contact connecting via 680 is formed on the second sacrificial semiconductor pattern 80_SC.

The fifth contact connecting via 580 may fill the third contact via hole 580H. The sixth contact connecting via 680 may fill the fourth contact via hole 380H.

The fifth connecting via silicide film 585 and the sixth connecting via silicide film 685 may be formed, while the fifth contact connecting via 580 and the sixth contact connecting via 680 are being formed.

The second upper interlayer insulating film 191 may be formed on the first upper interlayer insulating film 190, the fifth contact connecting via 580 and the sixth contact connecting via 680. The front wiring line 197 may be formed inside the second upper interlayer insulating film 191.

Unlike the shown example, in FIGS. 42 to 44, the third contact via hole 580H and the fourth contact via hole 680H may be formed after a part of the second upper interlayer insulating film 191 is formed. In such a case, the fifth contact connecting via 580 and the sixth contact connecting via 680 may be directly connected to the front wiring line 197.

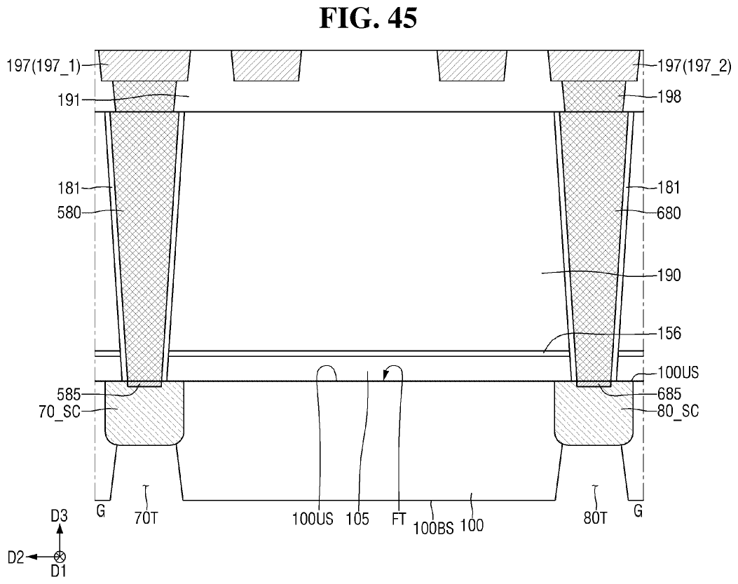

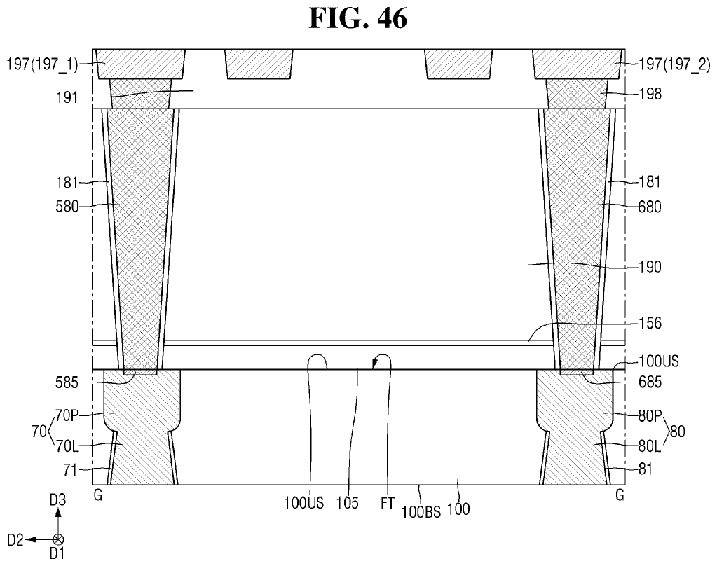

Referring to FIGS. 45 and 46, the first buried trench 70T that exposes the first sacrificial semiconductor pattern 70_SC may be formed.

The second buried trench 80T that exposes the second sacrificial semiconductor pattern 80_SC may be formed.

Subsequently, the first sacrificial semiconductor pattern 70_SC exposed by the first buried trench 70T may be removed. The second sacrificial semiconductor pattern 80_SC exposed by the second buried trench 80T may be removed.

The first buried conductive pattern 70 is then formed inside the first buried trench 70T. The second buried conductive pattern 80 is formed inside the second buried trench 80T.

In concluding the detailed description, those of ordinary skill in the art will appreciate that many variations and modifications may be made to various example embodiments without substantially departing from the principles of inventive concepts. Therefore, variously described example embodiments are used in a generic and descriptive sense only and not for purposes of limitation. Additionally example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
a substrate including a first side and a second side that are opposite to each other in a first direction;
a fin-shaped pattern protruding from the first side of the substrate in the first direction, and extending in a second direction;
a source/drain pattern on the fin-shaped pattern and connected to the fin-shaped pattern;
a source/drain contact on the source/drain pattern and connected to the source/drain pattern;
a back wiring line on the second side of the substrate;
a contact connecting via connected to the source/drain contact, and extending in the first direction; and
a buried conductive pattern inside the substrate, and connecting the contact connecting via and the back wiring line, wherein
the buried conductive pattern includes a first portion and a second portion,
the second portion of the buried conductive pattern is between the first portion of the buried conductive pattern and the contact connecting via,
at the first portion of the buried conductive pattern, a width in a third direction of the buried conductive pattern decreases, as the buried conductive pattern goes away from the back wiring line, and
at the second portion of the buried conductive pattern, the width in the third direction of the buried conductive pattern increases, as the buried conductive pattern goes away from the back wiring line.

2. The semiconductor device of claim 1, wherein
the buried conductive pattern further comprises a third portion between the second portion of the buried conductive pattern and the contact connecting via, and
at the third portion of the buried conductive pattern, the width of the buried conductive pattern in the third direction decreases, as the buried conductive pattern goes away from the back wiring line.

3. The semiconductor device of claim 1, wherein
the buried conductive pattern further comprises a third portion between the second portion of the buried conductive pattern and the contact connecting via, and
at the third portion of the buried conductive pattern, the width of the buried conductive pattern in the third direction is constant.

4. The semiconductor device of claim 1, wherein
the first portion of the buried conductive pattern has a line shape extending in the first direction, and
the second portion of the buried conductive pattern protrudes from the first portion of the buried conductive pattern in the first direction.

5. The semiconductor device of claim 1, further comprising:
a connecting via silicide film between the buried conductive pattern and the contact connecting via.

6. The semiconductor device of claim 1, further comprising:
a field insulating film which on the first side of the substrate and covering side walls of the fin-shaped pattern, wherein
a part of the contact connecting via is inside the field insulating film.

7. The semiconductor device of claim 1, wherein
the contact connecting via at least partly overlaps the source/drain contact in the third direction.

8. The semiconductor device of claim 1, further comprising:
a front wiring structure on the first side of the substrate, wherein
the front wiring structure includes a front wiring line extending in the second direction, and connecting the source/drain contact and the contact connecting via.

9. The semiconductor device of claim 1, wherein
the substrate includes a semiconductor substrate.

10. The semiconductor device of claim 1, wherein
the substrate comprises a semiconductor substrate and an insulating substrate, and
the semiconductor substrate comprises the first side of the substrate.

11. A semiconductor device comprising:
a substrate including a first side and a second side that are opposite to each other in a first direction;
a fin-shaped pattern protruding from the first side of the substrate in the first direction and extending in a second direction;
a source/drain pattern on the fin-shaped pattern and connected to the fin-shaped pattern;
a source/drain contact on the source/drain pattern and connected to the source/drain pattern;
a back wiring line on the second side of the substrate;
a contact connecting via connected to the source/drain contact and extending in the first direction;
a buried conductive pattern inside the substrate, and connecting the contact connecting via and the back wiring line; and
a connecting via silicide film between the buried conductive pattern and the contact connecting via, wherein
the buried conductive pattern includes a first portion and a second portion,
the second portion of the buried conductive pattern is between the first portion of the buried conductive pattern and the contact connecting via,
at the first portion of the buried conductive pattern, a width in a third direction of the buried conductive pattern is constant, and
at the second portion of the buried conductive pattern, the width in the third direction of the buried conductive pattern increases, as the buried conductive pattern goes away from the back wiring line.

12. The semiconductor device of claim 11, wherein
the buried conductive pattern further comprises a third portion between the second portion of the buried conductive pattern and the contact connecting via, and
at the third portion of the buried conductive pattern, the width of the buried conductive pattern in the third direction decreases, as the buried conductive pattern goes away from the back wiring line.

13. The semiconductor device of claim 11, wherein
the buried conductive pattern further comprises a third portion between the second portion of the buried conductive pattern and the contact connecting via, and
at the third portion of the buried conductive pattern, the width of the buried conductive pattern in the third direction is constant.

14. The semiconductor device of claim 11, wherein
the first portion of the buried conductive pattern has a line shape extending in the first direction, and
the second portion of the buried conductive pattern protrudes from the first portion of the buried conductive pattern in the first direction.

15. The semiconductor device of claim 11, wherein the contact connecting via at least partly overlaps the source/drain contact in the third direction.

16. The semiconductor device of claim 11, further comprising:
a front wiring structure disposed on the first side of the substrate, wherein
the front wiring structure includes a front wiring line extending in the second direction, and
the front wiring line connects the source/drain contact and the contact connecting via.

17. A semiconductor device comprising:
a substrate including a first side and a second side that are opposite to each other in a first direction;
a fin-shaped pattern protruding from the first side of the substrate in the first direction and extending in a second direction;
a source/drain pattern on the fin-shaped pattern and connected to the fin-shaped pattern;
a source/drain contact on the source/drain pattern and connected to the source/drain pattern;
a back wiring line on the second side of the substrate;
a contact connecting via connected to the source/drain contact and extending in the first direction; and
a buried conductive pattern inside the substrate and connecting the contact connecting via and the back wiring line, wherein
the buried conductive pattern includes a first portion and a second portion,
the second portion of the buried conductive pattern is between the first portion of the buried conductive pattern and the contact connecting via,
the first portion of the buried conductive pattern has a line shape extending in the first direction, and
the second portion of the buried conductive pattern protrudes from the first portion of the buried conductive pattern in the first direction.

18. The semiconductor device of claim 17, further comprising:
a connecting via silicide film between the buried conductive pattern and the contact connecting via.

19. The semiconductor device of claim 17, wherein
at the first portion of the buried conductive pattern, a width in a third direction of the buried conductive pattern decreases, as the buried conductive pattern goes away from the back wiring line, and
at the second portion of the buried conductive pattern, the width in the third direction increases of the buried conductive pattern, as the buried conductive pattern goes away from the back wiring line.

20. The semiconductor device of claim 17,
wherein at the first portion of the buried conductive pattern, a width in a third direction of the buried conductive pattern is constant, and
at the second portion of the buried conductive pattern, the width in the third direction of the buried conductive pattern increases, as it goes away from the back wiring line.
